(19) United States
(12) Patent Application Publication
(10) Pub. No.: US 2025/0254854 A1
(43) Pub. Date: Aug. 7, 2025

(54) SEMICONDUCTOR DEVICES

(71) Applicant: Samsung Electronics Co., Ltd., Suwon-si (KR)

(72) Inventors: SERYEUN YANG, Suwon-si (KR); JEON IL LEE, Suwon-si (KR); CHAE LYOUNG KIM, Suwon-si (KR); SEOHA LEE, Suwon-si (KR)

(21) Appl. No.: 18/780,635

(22) Filed: Jul. 23, 2024

(30) Foreign Application Priority Data
Feb. 5, 2024 (KR) 10-2024-0017523

(51) Int. Cl. H10B 12/00; H01L 23/00; H01L 25/065; H01L 25/18; H10B 80/00

(52) U.S. Cl. CPC H10B 12/315; H01L 24/08; H01L 25/0657; H01L 25/18; H10B 12/033; H10B 12/05; H10B 80/00; H01L 2224/08145; H01L 2924/1431; H01L 2924/1436

(57) ABSTRACT

Disclosed is a semiconductor device comprising a lower dielectric layer including a cell array region and a connection region; vertical channel patterns spaced apart from each other in a first direction and a second direction on the cell array region; gate lines spaced apart from each other in the first direction and extend in the second direction on the cell array region, wherein at least one of the vertical channel patterns is between the gate lines in the first direction; a capacitor structure on the cell array region, wherein the capacitor structure is connected to the vertical channel patterns; and a dummy structure on the connection region, wherein the dummy structure includes: dummy substrate patterns spaced apart from each other in the first direction and the second direction; and a peripheral dielectric layer between the dummy substrate patterns.

### CROSS-REFERENCE TO RELATED APPLICATIONS

This U.S. nonprovisional application claims priority under 35 U.S.C § 119 to Korean Patent Application No. 10-2024-0017523 filed on Feb. 5, 2024 in the Korean Intellectual Property Office, the disclosure of which is hereby incorporated by reference in its entirety.

### BACKGROUND OF THE INVENTION

The present inventive concepts relate to semiconductor devices, and more particularly, to semiconductor devices including vertical channel transistors.

A reduction in design rule of semiconductor devices induces development of fabrication technology to increase integration, operating speeds, and manufacturing yield of semiconductor devices. Accordingly, transistors with vertical channels have been suggested to increase their integration, resistance, current driving capability, and so forth.

### SUMMARY OF THE INVENTION

Some embodiments of the present inventive concepts may provide semiconductor devices having increased reliability and improved electrical characteristics.

Some embodiments of the present inventive concepts may provide semiconductor devices in which a bare silicon wafer is used to reduce costs and methods of fabricating the same.

The object of the present inventive concepts is not limited to the mentioned above, and other objects which have not been mentioned above will be clearly understood to those skilled in the art from the following description.

According to some embodiments of the present inventive concepts, a lower dielectric layer that includes a cell array region and a connection region that is adjacent the cell array region; a plurality of vertical channel patterns that are spaced apart from each other in a first direction and a second direction on the cell array region of the lower dielectric layer, wherein the first direction and the second direction are parallel with an upper surface of the lower dielectric layer and intersect with each other; a plurality of gate lines that are spaced apart from each other in the first direction and extend in the second direction on the cell array region of the lower dielectric layer, wherein at least one of the vertical channel patterns is between the gate lines in the first direction; a capacitor structure on the cell array region of the lower dielectric layer, wherein the capacitor structure is electrically connected to the vertical channel patterns; and a dummy structure on the connection region of the lower dielectric layer, wherein the dummy structure includes: a plurality of dummy substrate patterns that are spaced apart from each other in the first direction and the second direction; and a peripheral dielectric layer between the dummy substrate patterns.

According to some embodiments of the present inventive concepts, a semiconductor device may comprise: a lower dielectric layer that includes a cell array region and a connection region that is adjacent the cell array region; a plurality of vertical channel patterns that are spaced apart from each other in a first direction and a second direction on the cell array region of the lower dielectric layer, wherein the first direction and the second direction are parallel with an upper surface of the lower dielectric layer and intersect with each other; a plurality of gate lines that are spaced apart from each other in the first direction and extend in the second direction on the cell array region of the lower dielectric layer, wherein at least one of the vertical channel patterns is between the gate lines in the first direction; a capacitor structure on the cell array region of the lower dielectric layer, wherein the capacitor structure is electrically connected to the vertical channel patterns; and a dummy structure on the connection region of the lower dielectric layer, wherein an upper surface of each of the vertical channel patterns is coplanar with an upper surface of the dummy structure.

According to some embodiments of the present inventive concepts, a semiconductor device may comprise: a lower dielectric layer that includes a cell array region and a connection region that extends from the cell array region; a bit line on the cell array region of the lower dielectric layer, wherein the bit line extends in a first direction; a plurality of vertical channel patterns that are spaced apart from each other in the first direction on the bit line; a plurality of gate lines on the bit lines, wherein ones of the gate lines are adjacent to corresponding ones of the vertical channel patterns, the gate lines intersect the bit line and extend in a second direction that intersects the first direction; a capacitor structure on the vertical channel patterns, wherein the capacitor structure includes a plurality of lower electrodes that are spaced apart from each other in the first direction, a dielectric layer on the lower electrodes, and an upper electrode on the dielectric layer and the lower electrodes; and a dummy structure on the connection region of the lower dielectric layer, wherein the dummy structure includes: a plurality of dummy substrate patterns that are spaced apart from each other in the first direction; and a dummy dielectric pattern between the dummy substrate patterns.

### BRIEF DESCRIPTION OF DRAWINGS

FIG. 1 illustrates a block diagram showing a semiconductor device according to some embodiments of the present inventive concepts.

FIGS. 2 and 3 illustrate simplified perspective views showing a semiconductor device according to some embodiments of the present inventive concepts.

FIG. 4 illustrates a plan view showing a semiconductor device according to some embodiments of the present inventive concepts.

FIGS. 5A and 5B illustrate cross-sectional views respectively taken along lines A-A′ and B-B′ of FIG. 4.

FIGS. 6 to 9, 10A, 11A, 12A, 13A, and 14A illustrate cross-sectional views taken along line A-A′ of FIG. 4, showing a method of fabricating a semiconductor device according to some embodiments of the present inventive concepts.

FIGS. 10B, 11B, 12B, 13B, and 14B illustrate cross-sectional views taken along line B-B′ of FIG. 4, showing a method of fabricating a semiconductor device according to some embodiments of the present inventive concepts.

FIGS. 15 to 22 illustrate cross-sectional views showing a semiconductor device according to some embodiments of the present inventive concepts.

FIG. 23 illustrates a plan view showing a semiconductor device according to some embodiments of the present inventive concepts.

FIG. 24 illustrates a cross-sectional view taken along line A-A′ of FIG. 23.

FIGS. 25 to 35 illustrate cross-sectional views taken along line A-A′ of FIG. 23, showing a method of fabricating a semiconductor device according to some embodiments of the present inventive concepts.

FIGS. 36 to 39 illustrate cross-sectional views showing a semiconductor device according to some embodiments of the present inventive concepts.

FIG. 40 illustrates a plan view showing a semiconductor device according to some embodiments of the present inventive concepts.

FIG. 41 illustrates a cross-sectional view taken along line A-A′ of FIG. 40.

FIGS. 42 to 47 illustrate cross-sectional views taken along line A-A′ of FIG. 40, showing a method of fabricating a semiconductor device according to some embodiments of the present inventive concepts.

FIGS. 48 to 51 illustrate cross-sectional views showing a semiconductor device according to some embodiments of the present inventive concepts.

### DETAILED DESCRIPTION OF THE INVENTION

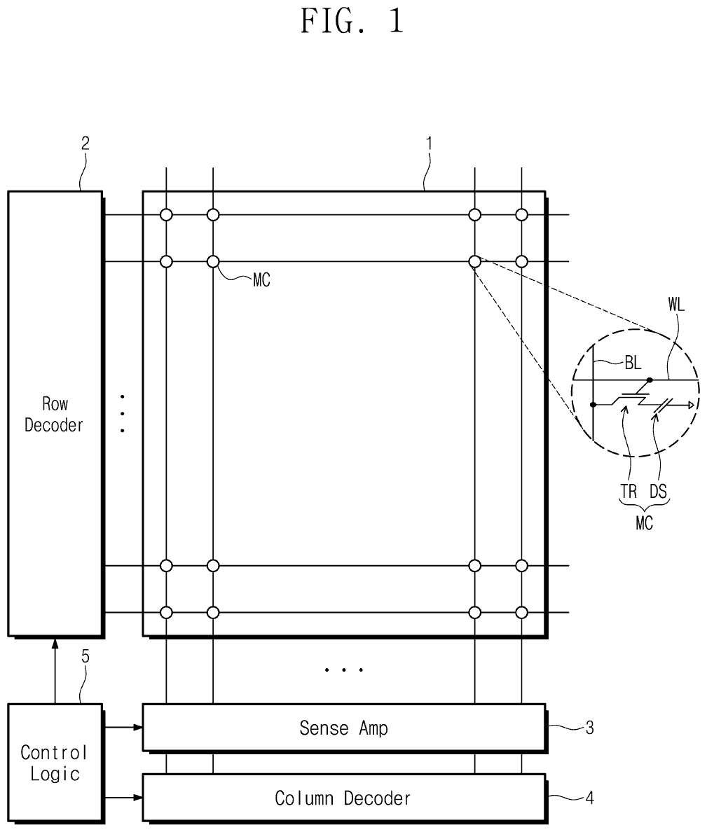

FIG. 1 illustrates a block diagram showing a semiconductor device according to some embodiments.

Referring to FIG. 1, a semiconductor device may include a memory cell array 1, a row decoder 2, a sense amplifier 3, a column decoder 4, and a control logic 5.

The memory cell array 1 may include a plurality of memory cells MC that are arranged two-dimensionally or three-dimensionally. Each of the memory cells MC may be connected to (between) a word line WL and a bit line BL that intersect each other. It will be understood that when an element or layer is referred to as being “on”, “connected to”, “responsive to”, or “coupled to” another element or layer, it may be directly on, connected to, responsive to, or coupled to the other element or layer, or one or more intervening elements or layers may be present. In contrast, when an element is referred to as being “directly on”, “directly connected to,” “directly responsive to,” or “directly coupled to”, another element, there are no intervening elements present. In addition, “electrical connection” conceptually includes a physical connection and a physical disconnection. Herein, a connection may refer to a physical connection and/or an electrical connection unless clearly stated otherwise.

Each of the memory cells MC may include a selection element TR and a data storage element DS. The selection element TR and the data storage element DS may be (electrically) connected to each other. The selection element TR may be connected to both of the word line WL and the bit line BL. For example, the selection element TR may be provided at an intersection between the word line WL and the bit line BL.

The selection element TR may include a field effect transistor. The data storage element DS may include a capacitor, a magnetic tunnel junction pattern, or a variable resistor. For example, a gate terminal of a transistor as the selection element TR may be connected to the word line WL, and source/drain terminals of the transistor may be connected to the bit line BL and the data storage element DS.

The row decoder 2 may decode an address that is externally input and may select one of the word lines WL of the memory cell array 1. The address decoded in the row decoder 2 may be provided to a row driver (not shown), and in response to a control operation of control circuits, the row driver may provide a certain voltage to a selected word line WL and each of non-selected word lines WL. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

In response to an address decoded from the column decoder 4, the sense amplifier 3 may detect and amplify a voltage difference between a selected bit line BL and a reference bit line BL (among a plurality of bit lines BL) and may then output the amplified voltage difference.

The column decoder 4 may provide a data delivery pathway between the sense amplifier 3 and an external device (e.g., a memory controller). The column decoder 4 may decode an address externally input and may select one of the bit lines BL.

The control logic 5 may generate control signals that control operations to write data to the memory cell array 1 and/or to read data from the memory cell array 1.

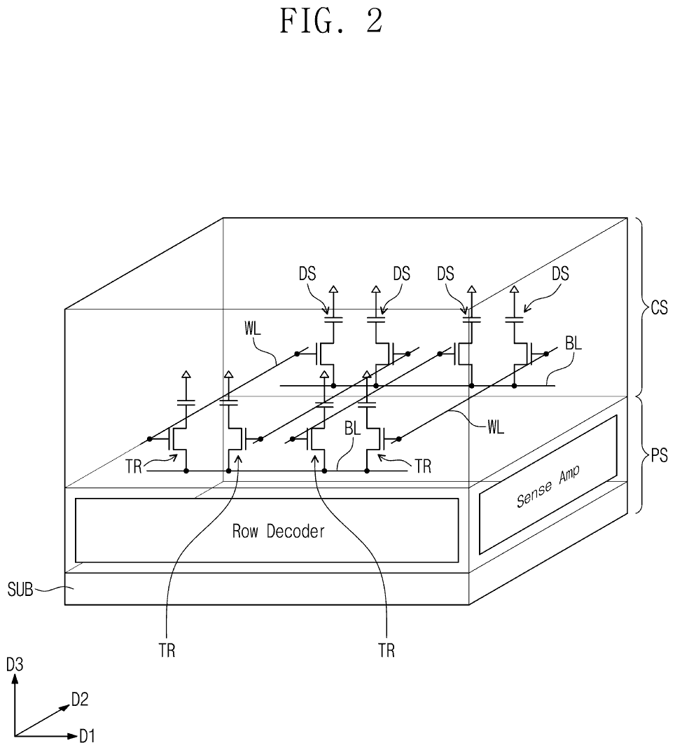

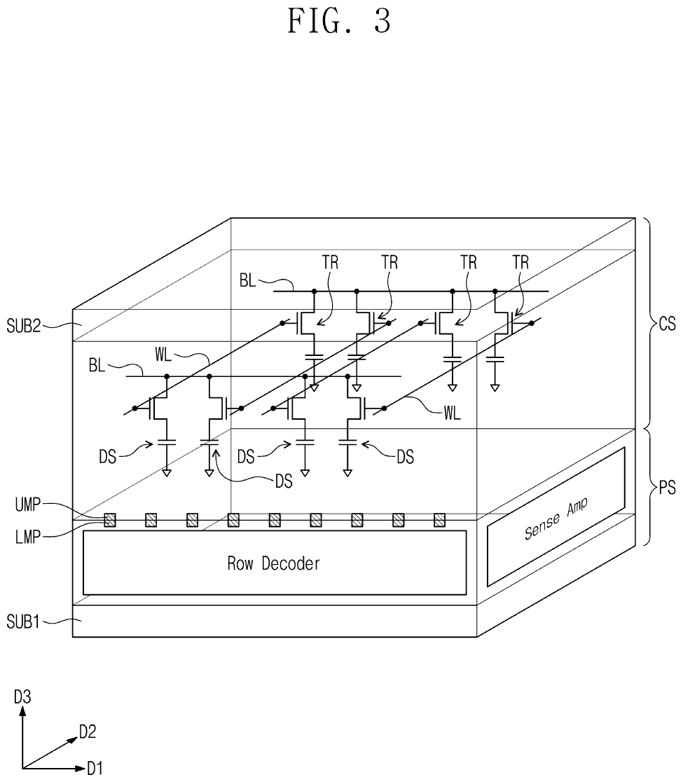

FIGS. 2 and 3 illustrate simplified perspective views showing a semiconductor device according to some embodiments.

Referring to FIGS. 2 and 3, a semiconductor device may include a peripheral circuit structure PS and a cell structure CS (stacked) on the peripheral circuit structure PS.

The peripheral circuit structure PS may include core/peripheral circuits formed on a substrate SUB. The core/peripheral circuits may include the row and column decoders 2 and 4, the sense amplifier 3, and the control logics 5 that are discussed with reference to FIG. 1.

The cell structure CS may include a memory cell array (e.g., the memory cell array 1 of FIG. 1) including two-dimensionally or three-dimensionally arranged memory cells (e.g., the memory cells MC of FIG. 1). Each of the memory cells (e.g., the memory cells MC of FIG. 1) may include, as discussed above, the selection element TR and the data storage element DS.

In some embodiments, a vertical channel transistor (VCT) may be included as the selection element TR of each memory cell (e.g., the memory cells MC of FIG. 1). The vertical channel transistor may include a channel whose lengthwise direction is perpendicular to an upper surface (e.g., a top surface) of the substrate SUB. A capacitor may be adopted as the data storage element DS of each of the memory cells (e.g., the memory cells MC of FIG. 1).

In the embodiment of FIG. 2, the peripheral circuit structure PS may be provided on the substrate SUB, and the cell structure CS may be provided on the peripheral circuit structure PS.

In the embodiment of FIG. 3, the peripheral circuit structure PS may be provided on a first substrate SUB1, and the cell structure CS may be provided on a second substrate SUB2. The first substrate SUB1 and the second substrate SUB2 may face each other. For example, the first substrate SUB1, the peripheral circuit structure PS, the cell structure CS, and the second substrate SUB2 may be sequentially stacked (in a direction perpendicular to an upper surface of the first substrate SUB1).

The peripheral circuit structure PS may be provided with first metal pads LMP on an upper (e.g., the uppermost) portion thereof. The first metal pads LMP may be electrically connected to the core/peripheral circuits (see 2, 3, 4, and 5 of FIG. 1).

The cell structure CS may be provided with second metal pads UMP on a lower (e.g., the lowermost) portion thereof. The second metal pads UMP may be electrically connected to the memory cell array (e.g., the memory cell array 1 of FIG. 1). The second metal pads UMP may be in (direct) contact with and/or bonded to the first metal pads LMP of the peripheral circuit structure PS.

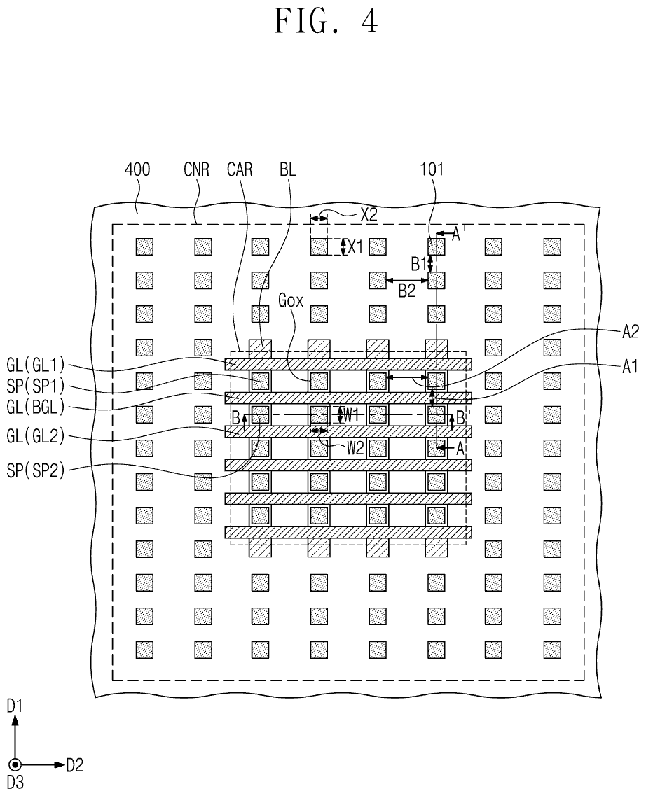

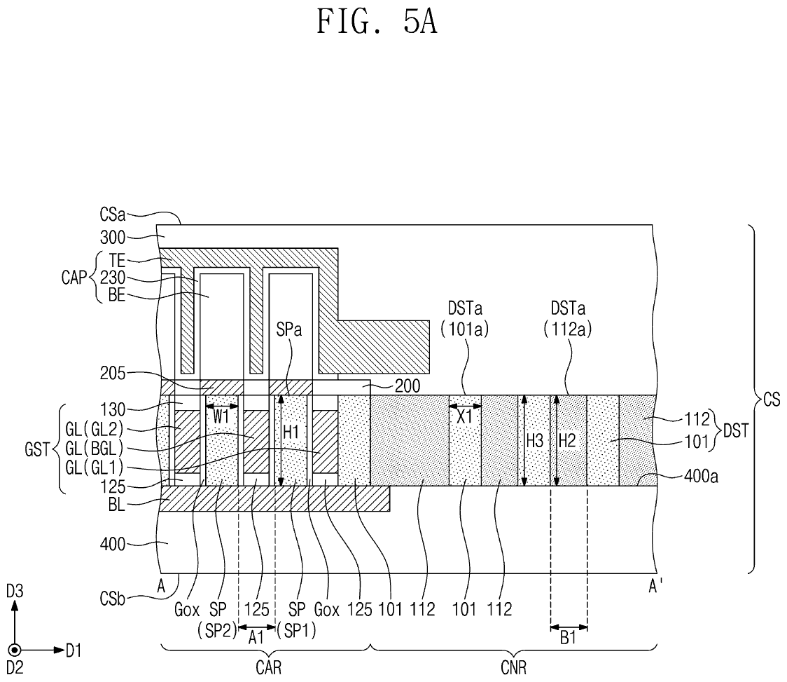

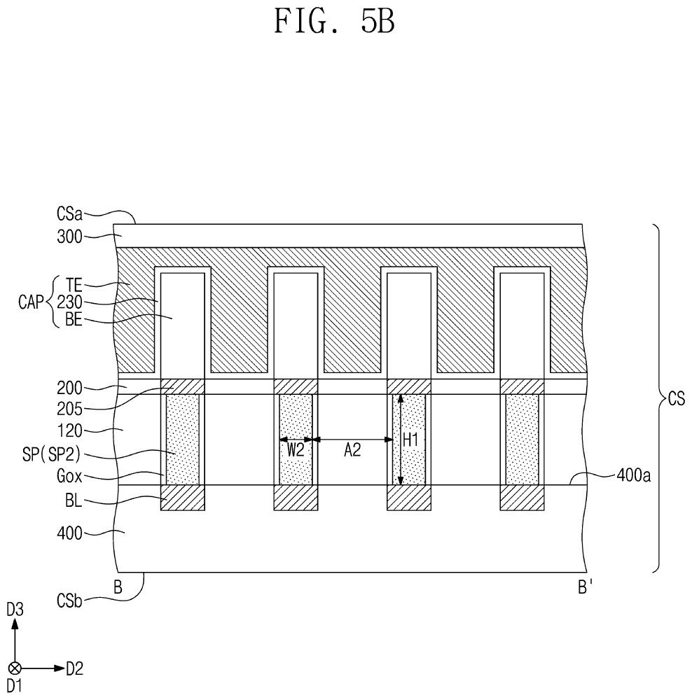

FIG. 4 illustrates a plan view showing a semiconductor device according to some embodiments of the present inventive concepts. FIGS. 5A and 5B illustrate cross-sectional views respectively taken along lines A-A′ and B-B′ of FIG. 4.

Referring to FIGS. 4, 5A, and 5B, a cell structure CS may be provided. The cell structure CS may include a lower dielectric layer 400 including a cell array region CAR and a connection region CNR. The lower dielectric layer 400 may extend in a first direction D1 and a second direction D2 that are oriented from the cell array region CAR toward the connection region CNR. In some embodiments, the cell array region CAR may be adjacent the connection region CNR. In this description, the first direction D1 and the second direction D2 may be parallel with an upper surface (e.g., a top surface) 400a of the lower dielectric layer 400 and intersect with each other. The first direction D1 and the second direction D2 may each be called a horizontal direction. A third direction D3 may be perpendicular to the upper surface (e.g., the top surface) 400a of the lower dielectric layer 400. The third direction D3 may be called a vertical direction. For example, the first direction D1, the second direction D2, and the third direction D3 may be orthogonal to each other.

When viewed in plan, the connection region CNR may extend from the cell array region CAR in the first direction D1 (or a direction opposite to the first direction D1) and the second direction D2 (or a direction opposite to the second direction D2). For example, in a plan view, the connection region CNR may extend around (e.g., surround) the cell array region CAR.

Differently from that shown, the lower dielectric layer 400 may include a plurality of stacked dielectric layers. The lower dielectric layer 400 may include a dielectric material, such as silicon oxide, silicon nitride, silicon oxynitride, and/or low-k dielectrics.

A bit line BL may be disposed in (on) the cell array region CAR of the lower dielectric layer 400. The bit line BL may extend along the first direction D1. The bit line BL may be provided in plural, and the plurality of bit lines BL may be spaced apart from each other in the second direction D2. The bit lines BL may have their upper surfaces (e.g., top surfaces) coplanar with the upper surface (e.g., top surface) 400a of the lower dielectric layer 400.

The bit line BL may include, for example, doped polysilicon, metal (e.g., Al, Cu, Ti, Ta, Ru, W, Mo, Pt, Ni, and/or Co), conductive metal nitride (e.g., TiN, TaN, WN, NbN, TiAlN, TiSiN, TaSiN, and/or RuTiN), conductive metal silicide, and/or conductive metal oxide (e.g., PtO, RuO₂, IrO₂, SRO(SrRuO₃), BSRO((Ba,Sr)RuO₃), CRO(CaRuO₃), and/or LSCo), but the present inventive concepts are not limited thereto. The bit line BL may include a single or multiple layer of one or more materials discussed above. In some embodiments, the bit line BL may include a two-dimensional semiconductor material, such as graphene, carbon nano-tube, and/or any combination thereof.

A vertical channel pattern SP may be disposed on the bit line BL in the cell array region CAR of the lower dielectric layer 400. The vertical channel pattern SP may have a lower surface (e.g., a bottom surface) in contact with the upper surface (e.g., the top surface) of the bit line BL. The vertical channel pattern SP may be connected to bit line BL. The vertical channel pattern SP may be provided in plural. The plurality of vertical channel patterns SP may be spaced apart from each other in the first direction D1 on one bit line BL. The vertical channel patterns SP may be disposed spaced apart from each other in the first direction D1 and the second direction D2 on a plurality of bit lines BL. Each of the vertical channel patterns SP may have a lower surface (e.g., a bottom surface) in contact with the upper surface (e.g., the top surface) of a corresponding one of the bit lines BL. Each of the vertical channel patterns SP may have a vertical channel structure whose channel length is elongated along the third direction D3. A lower portion of the vertical channel pattern SP may serve as a first source/drain section (not shown), an upper portion of the vertical channel pattern SP may serve as a second source/drain section (not shown), and a portion of the vertical channel pattern SP between the first and second source/drain sections may serve as a channel section (not shown).

The vertical channel pattern SP may have a first width W1 in the first direction D1 and a second width W2 in the second direction D2. The vertical channel pattern SP may have a first thickness H1 in the vertical direction D3. In this description, the term “thickness” may be measured in the vertical direction D3 from the upper surface (e.g., the top surface) 400a of the lower dielectric layer 400.

A gate structure GST may be disposed on the cell array region CAR of the lower dielectric layer 400. The gate structure GST may be provided in plural. The plurality of gate structures GST may be spaced apart from each other in the first direction D1. The gate structures GST may be disposed adjacent to the vertical channel patterns SP. In some embodiments, the gate structure GST may be between adjacent vertical channel patterns SP in the first direction D1. Each of the gate structures GST may include a gate line GL, a first buried layer 125, and a second buried layer 130. The gate lines GL may include a first gate line GL1, a second gate line GL2, and a back-gate line BGL.

The vertical channel patterns SP may be disposed between the gate lines GL (in the first direction D1), respectively. In some embodiments, at least one of the vertical channel patterns SP may be disposed between the gate lines GL in the first direction D1. For example, first vertical channel patterns SP1 may be defined to refer to the vertical channel patterns SP disposed adjacent to the first gate line GL1. Second vertical channel patterns SP2 may be defined to refer to the vertical channel patterns SP disposed adjacent to the second gate line GL2. The vertical channel patterns SP may be spaced apart from each other at a first distance A1 in the first direction D1. For example, one of the first vertical channel patterns SP1 may be spaced apart at the first distance A1 in the first direction D1 from one of the second vertical channel patterns SP2. The first vertical channel patterns SP1 may be spaced apart from each other at a second distance A2 in the second direction D2. The second vertical channel patterns SP2 may be spaced apart from each other at the second distance A2 in the second direction D2. For example, the vertical channel patterns SP may be spaced apart from each other at the second distance A2 in the second direction D2.

The back-gate line BGL may be disposed between the first vertical channel patterns SP1 and the second vertical channel patterns SP2. For example, the first vertical channel patterns SP1 may be disposed between the first gate line GL1 and the back-gate line BGL. The second vertical channel patterns SP2 may be disposed between the back-gate line BGL and the second gate line GL2. The first gate line GL1, the second gate line GL2, and the back-gate line BGL may extend in the second direction D2, while running across (e.g., intersecting or overlapping in the third direction D3) the bit line BL. The present inventive concepts, however, are not limited thereto. According to some embodiments, the back-gate line BGL may be omitted. Therefore, a semiconductor device may have a single gate transistor structure. As used herein, “an element A overlapping an element B in a direction X” (or similar language) means that there is at least one line that extends in the direction X and intersects both the elements A and B.

The first gate line GL1, the second gate line GL2, and the back-gate line BGL may include, for example, doped polysilicon, metal, conductive metal nitride, conductive metal silicide, conductive metal oxide, and/or any combination thereof. For example, the gate line GL may be formed of doped polysilicon, Al, Cu, Ti, Ta, Ru, W, Mo, Pt, Ni, Co, TiN, TaN, WN, NON, TiAl, TiAlN, TiSi, TiSiN, TaSi, TaSiN, RuTiN, NiSi, CoSi, IrOx, RuOx, and/or any combination thereof, but the present inventive concepts are not limited thereto.

The first buried layer 125 may be disposed between the upper surface (e.g., the top surface) of the bit line BL and a lower surface (e.g., a bottom surface) of each of the gate lines GL. The second buried layer 130 may be disposed on an upper surface (e.g., a top surface) of each of the gate lines GL. The first and second buried layers 125 and 130 may include, for example, a dielectric material, such as silicon oxide, silicon nitride, silicon oxynitride, and/or low-k dielectrics.

A gate dielectric layer Gox may be interposed between the gate structure GST and the vertical channel pattern SP (in the first direction D1). For example, the gate dielectric layer Gox may be interposed between the vertical channel pattern SP and the gate line GL of the gate structure GST. The gate dielectric layer Gox may extend between the first buried layer 125 and the vertical channel pattern SP (in the first direction D1) and between the second buried layer 130 and the vertical channel pattern SP (in the first direction D1). The gate dielectric layer Gox may be on (e.g., extend around or surround) sidewalls of each of the vertical channel patterns SP. Differently from that shown, according to some embodiments, the gate dielectric layer Gox may be in contact with only two of the sidewalls of the vertical channel patterns SP, which two sidewalls face the gate lines GL. The gate dielectric layer Gox may be omitted on two of the sidewalls of the vertical channel pattern SP, which two sidewalls do not face the gate lines GL. For example, the gate dielectric layer Gox may be disposed on the sidewalls of the vertical channel pattern SP opposite to (spaced apart from) each other in the first direction D1 and may be omitted on the sidewalls of the vertical channel pattern SP opposite to (spaced apart from) each other in the second direction D2.

The gate dielectric layer Gox may include, for example, a silicon oxide layer, a silicon oxynitride layer, a high-k dielectric layer whose dielectric constant is greater than that of a silicon oxide layer, and/or any combination thereof. The high-k dielectric layer may include (e.g., be formed of), for example, metal oxide and/or metal oxynitride. For example, the high-k dielectric layer may include HfO₂, HfSiO, HfSiON, HfTaO, HfTiO, HfZrO, ZrO₂, Al₂O₃, and/or any combination thereof.

A dielectric pattern 120 may be disposed between the vertical channel patterns SP that are spaced apart from each other in the second direction D2 and between the gate structures GST that are spaced apart from each other in the first direction D1. The dielectric pattern 120 may have a lower surface (e.g., a bottom surface) in contact with the upper surface (e.g., the top surface) 400a of the lower dielectric layer 400. A dummy substrate pattern 101 may be disposed on one side of the first gate line GL1 (with respect to the first direction D1). The dielectric pattern 120 may include, for example, a dielectric material, such as silicon oxide, silicon nitride, silicon oxynitride, and/or low-k dielectrics.

An interlayer dielectric layer 200 may be disposed on the gate structures GST on (in) the cell array region CAR of the lower dielectric layer 400. The interlayer dielectric layer 200 may extend onto the dummy substrate pattern 101 disposed on one side of the first gate line GL1 (with respect to the first direction D1).

A dummy structure DST may be disposed on (in) the connection region CNR of the lower dielectric layer 400. The dummy structure DST may include dummy substrate patterns 101 that are spaced apart from each other in the first and second directions D1 and D2. The dummy structure DST may include a peripheral dielectric layer 112 between the dummy substrate patterns 101.

Each of the dummy substrate patterns 101 may have a first width X1 in the first direction D1 and a second width X2 in the second direction D2. The first width X1 of the dummy substrate pattern 101 may be similar to the first width W1 in the first direction D1 of the vertical channel pattern SP. For example, the first width X1 in the first direction D1 of the dummy substrate pattern 101 may be the same as (may be equal to) the first width W1 in the first direction D1 of the vertical channel pattern SP. The second width X2 in the second direction D2 of the dummy substrate pattern 101 may be similar to the second width W2 in the second direction D2 of the vertical channel pattern SP. For example, the second width X2 in the second direction D2 of the dummy substrate pattern 101 may be the same as (may be equal to) the second width W2 in the second direction D2 of the vertical channel pattern SP.

The peripheral dielectric layer 112 may have a second thickness H2 in the vertical direction D3. Each of the dummy substrate patterns 101 may have a third thickness H3 in the vertical direction D3. The first thickness H1 in the vertical direction D3 of the vertical channel pattern SP may be the same as (may be equal to) the second thickness H2 of the peripheral dielectric layer 112 and the third thickness H3 of the dummy substrate pattern 101. For example, an upper surface (e.g., a top surface) SPa of the vertical channel pattern SP may be coplanar with an upper surface (e.g., a top surface) DSTa of the dummy structure DST. The upper surface (e.g., the top surface) SPa of the vertical channel pattern SP may be coplanar with an upper surface (e.g., a top surface) 112a of the peripheral dielectric layer 112 and an upper surface (e.g., a top surface) 101a of the dummy substrate pattern 101.

The dummy substrate patterns 101 may be spaced apart from each other at a first distance B1 in the first direction D1. The dummy substrate patterns 101 may be spaced apart from each other at a second distance B2 in the second direction D2. The first distance B1 at which the dummy substrate patterns 101 are spaced apart from each other in the first direction D1 may be similar to the first distance A1 at which the vertical channel patterns SP are spaced apart from each other in the first direction D1. For example, the first distance B1 at which the dummy substrate patterns 101 are spaced apart from each other in the first direction D1 may be the same as (may be equal to) the first distance A1 at which the vertical channel patterns SP are spaced apart from each other in the first direction D1. In this sense, the first distance B1 at which the dummy substrate patterns 101 are spaced apart from each other in the first direction D1 may be the same as (may be equal to) the first distance A1 at which one of the first vertical channel patterns SP1 is spaced apart in the first direction D1 from one of the second vertical channel patterns SP2. The second distance B2 at which the dummy substrate patterns 101 are spaced apart from each other in the second direction D2 may be similar to the second distance A2 at which the vertical channel patterns SP are spaced apart from each other in the second direction D2. In this sense, the second distance B2 at which the dummy substrate patterns 101 are spaced apart from each other in the second direction D2 may be the same as (may be equal to) the second distance A2 at which the vertical channel patterns SP are spaced apart from each other in the second direction D2.

According to the present inventive concepts, the vertical channel patterns SP and the dummy substrate patterns 101 may have a similar or the same (equal) spacing distance in the horizontal directions D1 and D2. In addition, the vertical channel patterns SP and the dummy substrate patterns 101 may have a similar or the same (equal) width in the horizontal directions D1 and D2. For example, the cell array region CAR and the connection region CNR may have their pattern densities that are similar (or equal) to each other. Therefore, in a subsequently described method of fabricating a semiconductor device according to the present inventive concepts, a dishing phenomenon may be reduced (e.g., prevented) when a planarization process is performed, and a semiconductor device may improve in reliability and electrical characteristics.

Capacitor contacts 205 may be correspondingly disposed on the vertical channel patterns SP. The capacitor contacts 205 may be disposed in the interlayer dielectric layer 200. The capacitor contacts 205 may be in (direct) contact with the upper surfaces (e.g., the top surfaces) SPa of corresponding vertical channel patterns SP. When viewed in plan, the capacitor contacts 205 may vertically overlap (may overlap in the third direction D3) corresponding vertical channel patterns SP. The capacitor contacts 205 may have their upper surfaces (e.g., top surfaces) coplanar with that of the interlayer dielectric layer 200. The capacitor contacts 205 may include (e.g., be formed of), for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, and/or any combination thereof, but the present inventive concepts are not limited thereto.

A capacitor structure CAP may be disposed on the interlayer dielectric layer 200. The capacitor structure CAP may include lower electrodes (e.g., bottom electrodes) BE that are horizontally spaced apart from each other, a dielectric layer 230 that is on (e.g., that covers) the lower electrodes (e.g., the bottom electrodes) BE, and an upper electrode (e.g., a top electrode) TE that is on (e.g., that covers) the dielectric layer 230 and the upper electrodes (e.g., the bottom electrodes) BE. The dielectric layer 230 may be interposed between the lower electrodes (e.g., the bottom electrodes) BE and the upper electrode (e.g., the top electrode) TE.

The lower electrodes (e.g., the bottom electrodes) BE may be correspondingly in contact with and electrically connected to the capacitor contacts 205. When viewed in plan, each of the lower electrodes (e.g., the bottom electrodes) BE may have a circular shape, an oval shape, a rectangular shape, a square shape, a rhombic shape, a hexagonal shape, or any other suitable shape. The lower electrodes (e.g., the bottom electrodes BE and the upper electrode (e.g., the top electrode) TE may include, for example, impurity-doped polysilicon, metal nitride such as titanium nitride, and/or metal such as tungsten, aluminum, and copper.

A first upper dielectric layer 300 may be disposed on (to cover) the capacitor structure CAP and the dummy structure DST on (in) the connection region CNR. An upper surface (e.g., a top surface) CSa of the first upper dielectric layer 300 and a lower surface (e.g., a bottom surface) CSb of the lower dielectric 400 may be opposite to (spaced apart from) each other in the third direction D3.

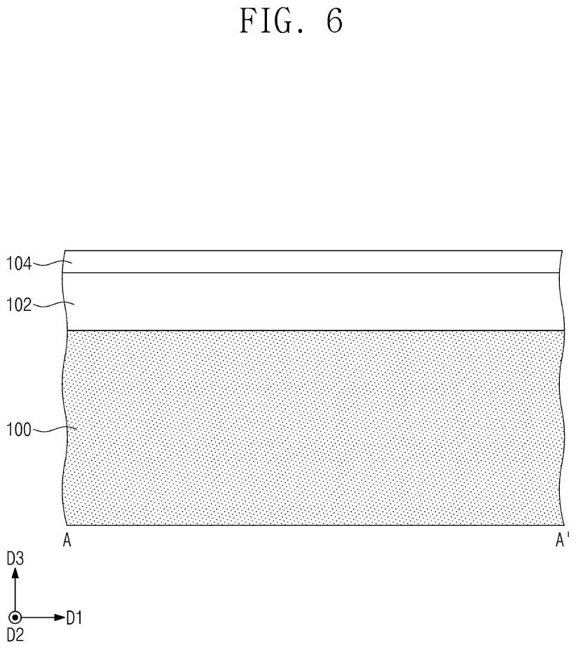

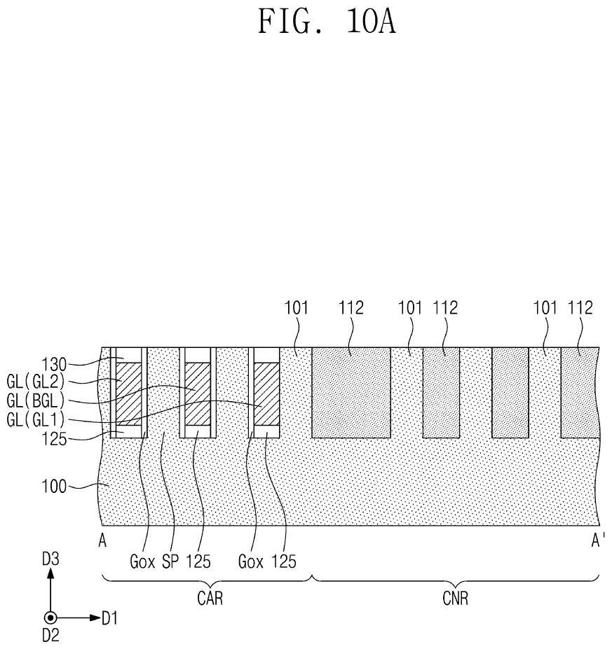

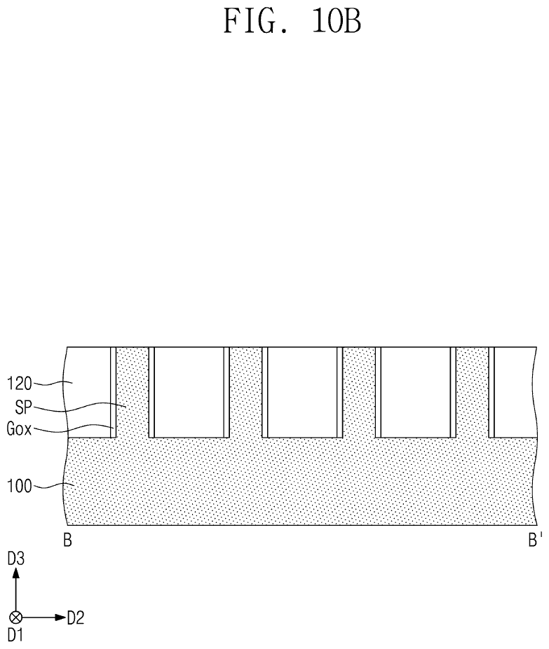

FIGS. 6 to 9, 10A, 11A, 12A, 13A, and 14A illustrate cross-sectional views taken along line A-A′ of FIG. 4, showing a method of fabricating a semiconductor device according to some embodiments of the present inventive concepts. FIGS. 10B, 11B, 12B, 13B, and 14B illustrate cross-sectional views taken along line B-B′ of FIG. 4, showing a method of fabricating a semiconductor device according to some embodiments of the present inventive concepts. For brevity of description, a repetitive explanation may be omitted.

Referring to FIG. 6, a substrate 100 may be provided. The substrate 100 may be a bare silicon wafer. A first sacrificial layer 102 and a second sacrificial layer 104 may be sequentially formed on the substrate 100. For example, the first sacrificial layer 102 may be disposed between the substrate 100 and the second sacrificial layer 104 in the third direction D3. The first and second sacrificial layers 102 and 104 may be formed by using a film formation technique, such as physical vapor deposition (PVD) and/or chemical vapor deposition (CVD). The first and second sacrificial layers 102 and 104 may include, for example, a dielectric material.

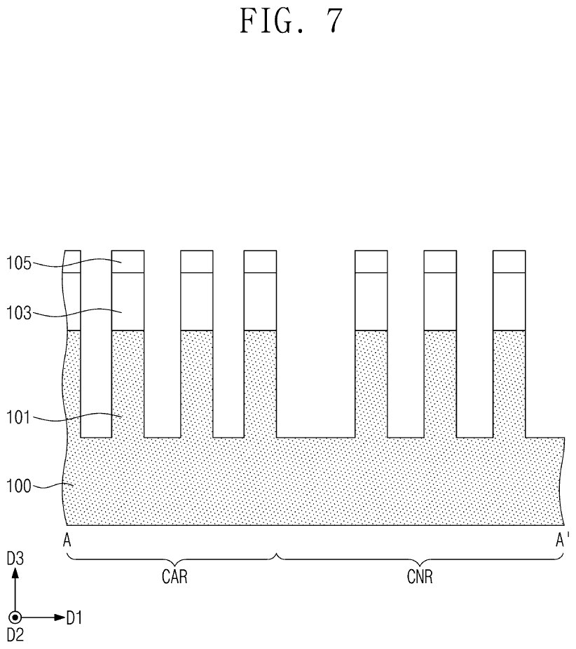

Referring to FIG. 7, dummy substrate patterns 101 may be formed on (in) a cell array region CAR and a connection region CNR of the substrate 100. For example, the dummy substrate patterns 101 may be formed in upper portions of the substrate 100 in the cell array region CAR and the connection region CNR. First sacrificial patterns 103 and second sacrificial patterns 105 may be formed on the dummy substrate patterns 101. A pattern structure may include the dummy substrate pattern 101, the first sacrificial pattern 103, and the second sacrificial pattern 105. The pattern structure may be provided in plural. The plurality of the pattern structures may be spaced apart from each other in horizontal directions D1 and D2. The formation of the dummy substrate patterns 101, the first sacrificial patterns 103, and the second sacrificial patterns 105 may include, for example, forming a mask pattern (not shown) on the second sacrificial layer 104, using the mask pattern as an etching mask to pattern the second sacrificial layer 104, the first sacrificial layer 102, and an upper portion of the substrate 100, and removing the mask pattern. The patterning may be performed through an anisotropic etching process.

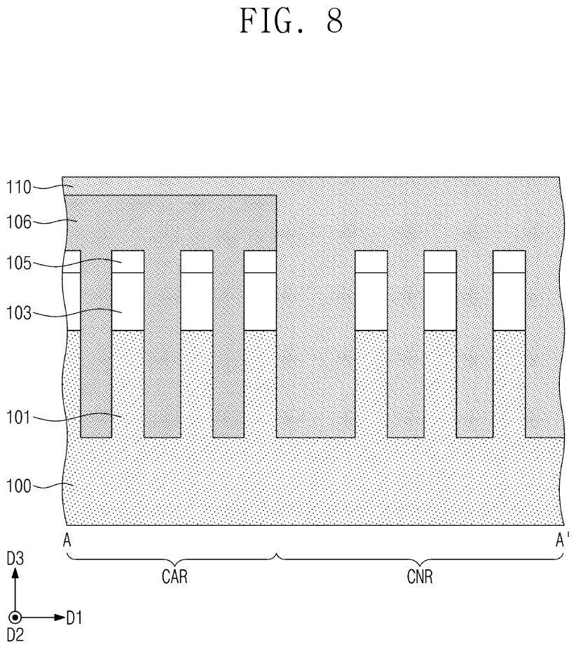

Referring to FIG. 8, a third sacrificial layer 106 may be formed on the cell array region CAR of the substrate 100, filling spaces between (each of) the pattern structures (e.g., the dummy substrate patterns 101, the first sacrificial patterns 103, and/or the second sacrificial patterns 105). A separation dielectric layer 110 may be formed on the connection region CNR of the substrate 100, filling spaces between (each of) the pattern structures (e.g., the dummy substrate patterns 101, the first sacrificial patterns 103, and/or the second sacrificial patterns 105). The separation dielectric layer 110 may extend onto the cell array region CAR to be on (e.g., to cover or overlap in the third direction D3) an upper surface (e.g., a top surface) of the third sacrificial layer 106.

The third sacrificial layer 106 may include a carbon-containing material. For example, the third sacrificial layer 106 may include a spin-on-hardmask (SOH) layer or an amorphous carbon layer (ACL). The separation dielectric layer 110 may include a dielectric material, such as silicon oxide, silicon nitride, silicon oxynitride, and/or low-k dielectric materials.

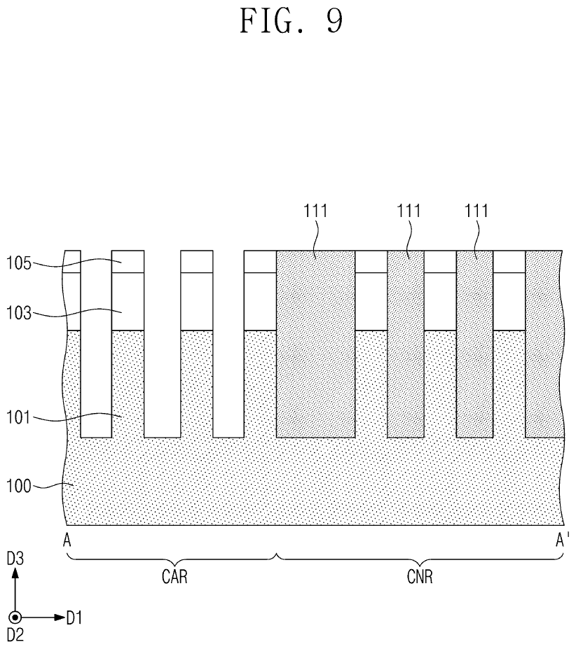

Referring to FIG. 9, a preliminary peripheral dielectric layer 111 may be formed on (in) the connection region CNR of the substrate 100. The preliminary peripheral dielectric layer 111 may be formed between the dummy substrate patterns 101 on (in) the connection region CNR. The formation of the preliminary peripheral dielectric layer 111 may include, for example, planarizing the separation dielectric layer 110 and the third sacrificial layer 106 until an upper surface (e.g., a top surface) of the second sacrificial pattern 105 is exposed. The planarization process may include, for example, a chemical mechanical polishing (CMP) process or an etch-back process.

The third sacrificial layer 106 may be removed on (in) the cell array region CAR of the substrate 100. The third sacrificial layer 106 may be removed by, for example, an ashing process and/or a wet etching process.

Referring to FIGS. 10A and 10B, there may be formed first buried layers 125, second buried layers 130, gate lines GL, a gate dielectric layer Gox, vertical channel patterns SP, a peripheral dielectric layer 112, and a dielectric pattern 120.

The formation of the vertical channel patterns SP may include, for example, implanting impurities into the dummy substrate patterns 101 on (in) the cell array region CAR and performing an annealing process. In a case of NMOS, the implantation process may include implanting, for example, one or both of arsenic (As) and phosphorus (P), and in a case of PMOS, the implantation process may include implanting, for example, boron (B).

The gate dielectric layer Gox may be formed to be on (e.g., extend around or surround) sidewalls of each of the vertical channel patterns SP. For example, in a plan view, the gate dielectric layer Gox may surround each of the vertical channel patterns SP. The gate dielectric layer Gox may be formed by using a film formation technique (whose step coverage is excellent), such as chemical vapor deposition (CVD), physical vapor deposition (PVD), and/or atomic layer deposition (ALD).

The formation of the first buried layers 125, the gate lines GL, the second buried layers 130, and the dielectric pattern 120 may include using a film formation technique, such as chemical vapor deposition (CVD) and/or physical vapor deposition (PVD).

The first and second sacrificial patterns 103 and 105 may be removed. The removal of the first and second sacrificial patterns 103 and 105 may be achieved through a planarization process. In the planarization process, an upper portion of the preliminary peripheral dielectric layer 111 may be etched to form a peripheral dielectric layer 112.

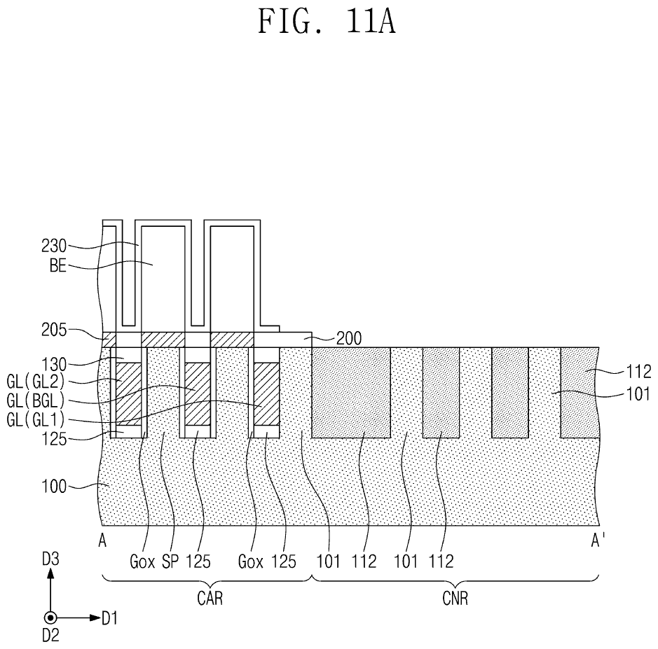

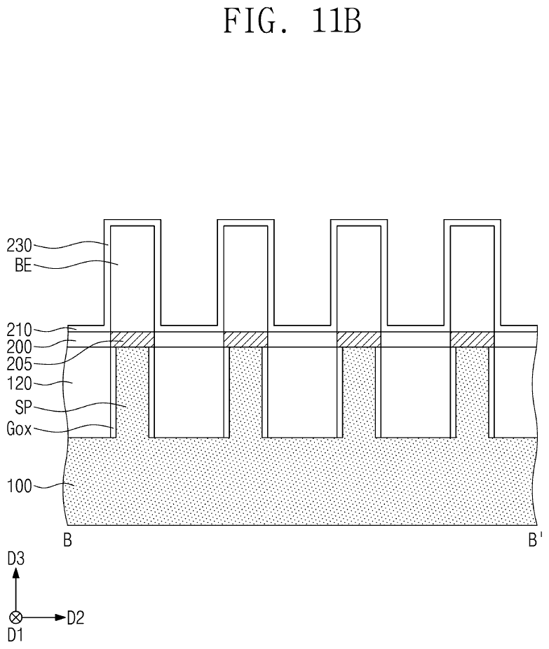

Referring to FIGS. 11A and 11B, an interlayer dielectric layer 200 may be formed on (in) the cell array region CAR, covering (e.g., overlapping in the third direction D3) the dielectric pattern 120 and the second buried layer 130. A capacitor contact 205 may be formed in the interlayer dielectric layer 200. A lower electrode (e.g., a bottom electrode) BE may be formed on the capacitor contact 205. The formation of the lower electrode (e.g., the bottom electrode) BE may include forming a lower electrode layer (e.g., a bottom electrode layer) (not shown), and then patterning the lower electrode layer (e.g., the bottom electrode layer). The lower electrode (e.g., the bottom electrode) BE may be formed in plural. A dielectric layer 230 may be formed on (e.g., to cover or overlap) the lower electrodes (e.g., the bottom electrodes) BE. The dielectric layer 230 may conformally cover the lower electrodes (e.g., the bottom electrodes) BE.

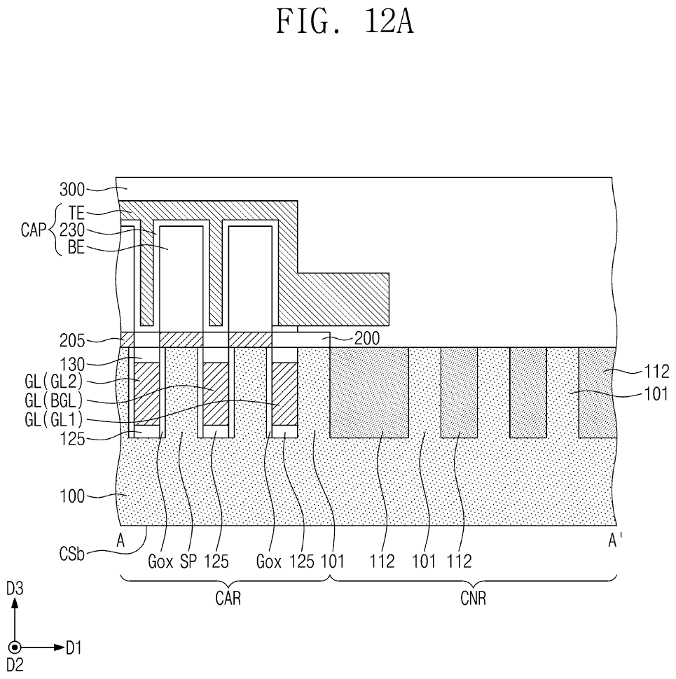

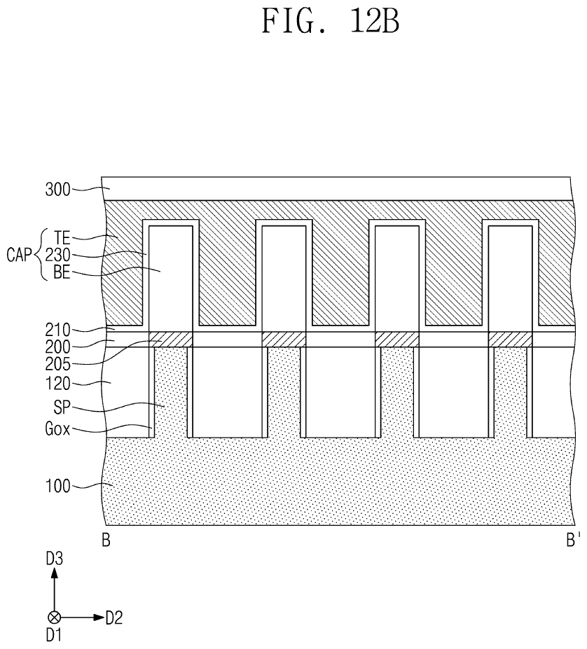

Referring to FIGS. 12A and 12B, a capacitor structure CAP may be formed. The formation of the capacitor structure CAP may include forming an upper electrode (e.g., a top electrode) TE that is on (e.g., covers) the dielectric layer 230. A first upper dielectric layer 300 may be formed on (e.g., to cover) the capacitor structure CAP and the dummy structure DST on (in) the connection region CNR.

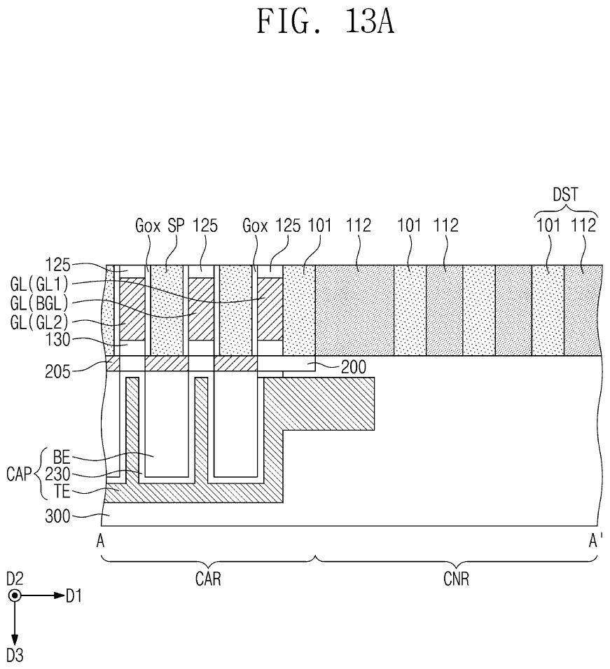

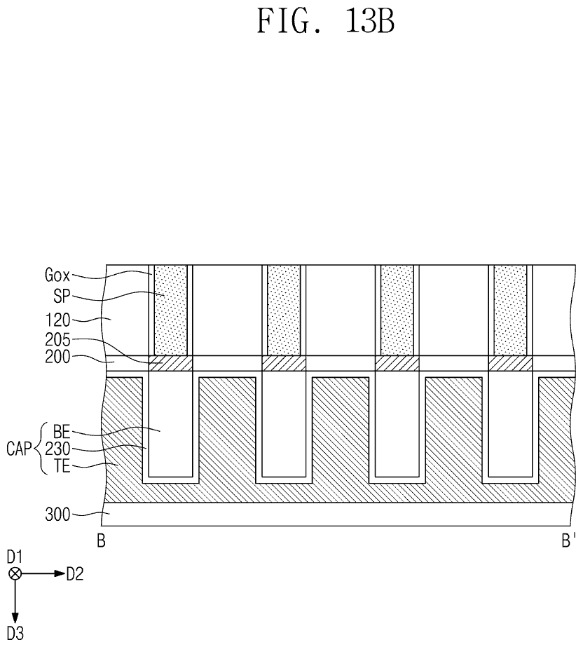

Referring to FIGS. 13A and 13B, a resultant structure discussed with reference to FIGS. 12A and 12B may be turned upside down. For example, the resultant structure may be overturned to allow the first upper dielectric layer 300 to face downwards and the substrate 100 to face upwards. After the resultant structure is overturned, the substrate 100 may be removed. The removal of the substrate 100 may include, for example, performing a planarization process until the peripheral dielectric layer 112 is exposed. The planarization process may include, for example, a chemical mechanical polishing (CMP) process or an etch-back process.

According to the present inventive concepts, as discussed with reference to FIGS. 4, 5A, and 5B, the cell array region CAR and the connection region CNR may have their pattern densities that are similar (or equal) to each other. Therefore, a dishing phenomenon may be reduced (e.g., prevented) during the planarization process, and a semiconductor device may improve in reliability and electrical characteristics.

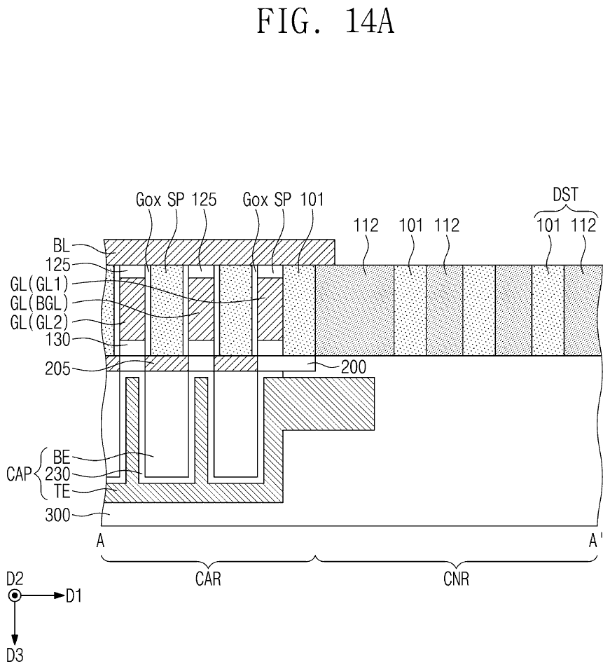

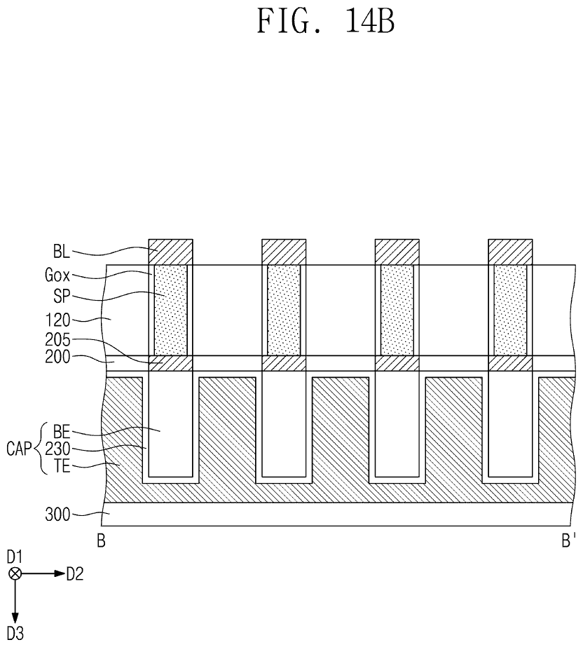

Referring to FIGS. 14A and 14B, a bit line BL may be formed on (in) the cell array region CAR. The formation of the bit line BL may include, for example, forming a bit line layer (not shown), forming a mask pattern (not shown) on the bit line layer, using the mask pattern as an etching mask to pattern the bit line layer, and removing the mask pattern. The bit line BL may be formed in plural. The plurality of bit lines BL may be formed in contact with corresponding vertical channel patterns SP.

Referring back to FIGS. 5A and 5B, a lower dielectric layer 400 may be formed to be on (e.g., entirely cover) (all the elements in) the cell array region CAR and the connection region CNR.

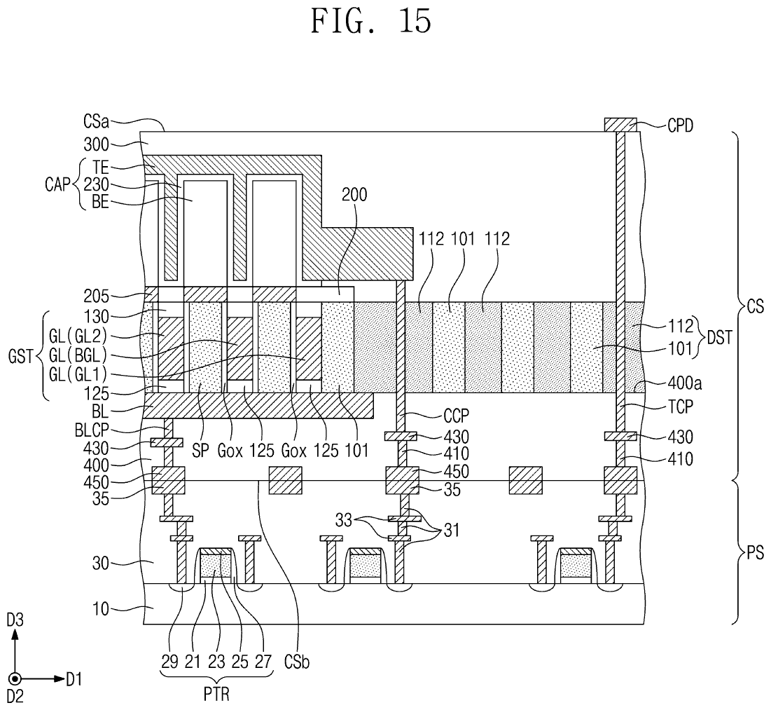

FIGS. 15 to 22 illustrate cross-sectional views showing a semiconductor device according to some embodiments of the present inventive concepts. For brevity of description, a repetitive explanation may be omitted.

Referring to FIG. 15, according to some embodiments, a bit-line contact plug BLCP may be disposed in the lower dielectric layer 400. The bit-line contact plug BLCP may be connected to the bit line BL. The bit-line contact plug BLCP may be electrically connected to a first bonding pad 450 through connection circuit lines 430 and connection contact plugs 410. The connection circuit lines 430 and the connection contact plugs 410 may include a conductive material, such as metal.

A capacitor contact plug CCP may be disposed to extend in (e.g., penetrate) the dummy structure DST, (a portion of) the lower dielectric layer 400, and (a portion of) the first upper dielectric layer 300. The capacitor contact plug CCP may be connected to the capacitor structure CAP. The capacitor contact plug CCP may be electrically connected to the first bonding pad 450 through the connection circuit lines 430 and the connection contact plugs 410.

A connection pad CPD may be disposed on the first upper dielectric layer 300. A through contact plug TCP may be disposed to extend in (e.g., penetrate) the first upper dielectric layer 300, the dummy structure DST, and (a portion of) the lower dielectric layer 400. The through contact plug TCP may be connected to the connection pad CPD. The through contact plug TCP may be electrically connected to the first bonding pad 450 through the connection circuit lines 430 and the connection contact plugs 410.

The first bonding pad 450 may be provided in plural. The plurality of first bonding pads 450 may be disposed adjacent to a lower surface (e.g., a bottom surface) CSb of the lower dielectric layer 400. The lower surface (e.g., the bottom surface) CSb of the lower dielectric layer 400 may not cover lower surfaces (e.g., bottom surfaces) of the first bonding pads 450. For example, the lower surfaces of the first bonding pads 450 may be exposed from the lower dielectric layer 400. The lower surface (e.g., the bottom surface) CSb of the lower dielectric layer 400 may be coplanar with the lower surfaces (e.g., the bottom surfaces) of the first bonding pads 450.

A peripheral circuit structure PS may be disposed on the lower surface (e.g., the bottom surface) CSb of the lower dielectric layer 400. The peripheral circuit structure PS may include peripheral circuit transistors PTR on (in) a peripheral substrate 10, peripheral contact plugs 31, peripheral circuit lines 33 electrically connected through the peripheral contact plugs 31 to the peripheral circuit transistors PTR, and a first dielectric layer 30 that extends around (e.g., surrounds) the peripheral circuit transistors PTR, the peripheral contact plugs 31, and the peripheral circuit lines 33. For example, at least a portion of the peripheral circuit transistor PTR, the peripheral contact plugs 31, and the peripheral circuit lines 33 may be in the first dielectric layer 30.

In some embodiments, a peripheral circuit may include (e.g., may be constituted by) the peripheral circuit transistors PTR, the peripheral contact plugs 31, and the peripheral circuit lines 33. In some embodiments, each of the peripheral circuit transistors PTR may include a peripheral gate dielectric layer 21, a peripheral gate electrode 23, a peripheral capping pattern 25, a peripheral gate spacer 27, and peripheral source/drain sections 29.

The peripheral gate dielectric layer 21 may be disposed between the peripheral gate electrode 23 and the peripheral substrate 10 (in the third direction D3). The peripheral capping pattern 25 may be disposed on the peripheral gate electrode 23. The peripheral gate spacer 27 may be on (e.g., may cover) a sidewall of the peripheral gate dielectric layer 21, a sidewall of the peripheral gate electrode 23, and/or a sidewall of the peripheral capping pattern 25. The peripheral source/drain sections 29 may be provided in the peripheral substrate 10 adjacent to opposite sides of the peripheral gate electrode 23 (in the first direction D1).

The peripheral circuit lines 33 may be electrically connected through the peripheral contact plugs 31 to the peripheral circuit transistors PTR. Each of the peripheral circuit transistors PTR may be, for example, an NMOS transistor, a PMOS transistor, or a gate-all-around type transistor. The peripheral contact plugs 31 and the peripheral circuit lines 33 may include a conductive material, such as metal.

The first dielectric layer 30 may be provided on an upper surface (e.g., a top surface) of the peripheral substrate 10. On the peripheral substrate 10, the first dielectric layer 30 may be disposed on (e.g., cover, extend around, or surround) the peripheral circuit transistors PTR, the peripheral contact plugs 31, and the peripheral circuit lines 33. The first dielectric layer 30 may include a plurality of dielectric layers that constitute a multi-layered structure. For example, the first dielectric layer 30 may include silicon oxide, silicon nitride, silicon oxynitride, and/or low-k dielectrics.

Second bonding pads 35 may be disposed to have electrical connection to the peripheral circuit transistors PTR through the peripheral contact plugs 31 and the peripheral circuit lines 33. The first dielectric layer 30 may not cover upper surfaces (e.g., top surfaces) of the second bonding pads 35. An upper surface (e.g., a top surface) of the first dielectric layer 30 may be coplanar with the upper surfaces (e.g., the top surfaces) of the second bonding pads 35. For example, the upper surfaces of the second bonding pads 35 may be exposed from the first dielectric layer 30.

The lower surfaces (e.g., the bottom surfaces) of the first bonding pads 450 may be correspondingly in (direct) contact with the upper surfaces (e.g., the top surfaces) of the second bonding pads 35. The first and second bonding pads 450 and 35 may include, for example, metal, such as copper (Cu), tungsten (W), aluminum (Al), nickel (Ni), and/or tin (Sn). For example, the first and second bonding pads 450 and 35 may include copper (Cu). The first bonding pad 450 and the second bonding pad 35 may constitute a single unitary shape without any interface therebetween. Although the first and second bonding pads 450 and 35 are illustrated to have their sidewalls linearly aligned with each other (in the third direction D3), the present inventive concepts are not limited thereto, and when viewed in plan, the first and second bonding pads 450 and 35 may have their sidewalls spaced apart from each other.

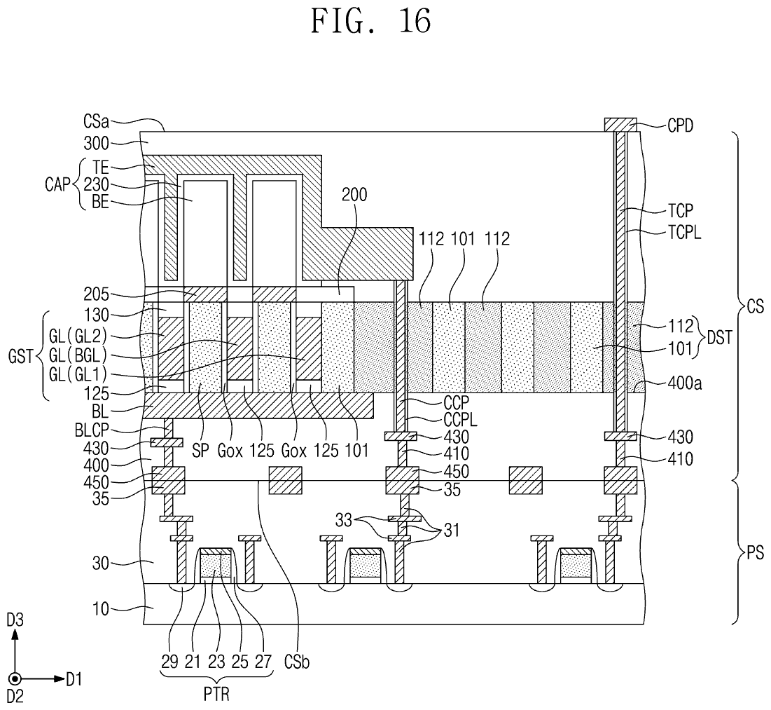

Referring to FIG. 16, according to some embodiments, a semiconductor device of FIG. 15 may further include a through plug line layer TCPL that (conformally) extends around (e.g., surrounds) a lateral surface (a side surface) of the through contact plug TCP. The through plug line layer TCPL may be interposed between the lateral surface of the through contact plug TCP and each of the first upper dielectric layer 300, the dummy structure DST, and the lower dielectric layer 400.

A semiconductor device of FIG. 15 may further include a capacitor plug line layer CCL that (conformally) covers (extends around or surrounds) a lateral surface (a side surface) of the capacitor contact plug CCP. The capacitor plug line layer CCL may be interposed between the lateral surface of the capacitor contact plug CCP and each of the first upper dielectric layer 300, the dummy structure DST, and the lower dielectric layer 400.

The through plug line layer TCPL and the capacitor plug line layer CCL may include, for example, a dielectric material. In some embodiments, differently from that shown, the though contact plug TCP and the capacitor contact plug CCP may extend in (e.g., penetrate) the dummy substrate pattern 101. In this case, the through plug line layer TCPL and the capacitor plug line layer CCL may be included for respectively insulating the through contact plug TCP and the capacitor contact plug CCP from the dummy substrate pattern 101.

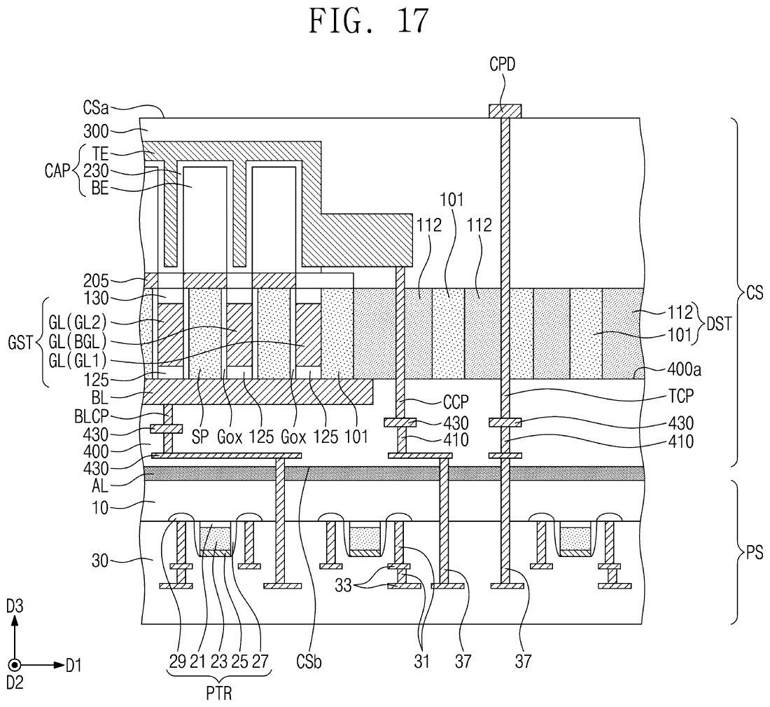

Referring to FIG. 17, according to some embodiments, an interface layer AL may be disposed on the lower surface (e.g., the bottom surface) CSb of the lower dielectric layer 400. The peripheral circuit structure PS may be disposed on a lower surface (e.g., a bottom surface) of the interface layer AL. The peripheral circuit structure PS may include peripheral through contacts 37 electrically connected to the peripheral circuit transistors PTR through the peripheral contact plugs 31 and the peripheral circuit lines 33. The peripheral through contacts 37 may extend in (e.g., penetrate) the peripheral circuit structure PS and the interface layer AL to come into electrical connection with the connection circuit lines 430.

The interface layer AL may have a single-layered or multi-layered structure of, for example, silicon carbonitride (SiCN) and/or silicon oxide. The formation of the interface layer AL may include, for example, forming a first interface layer (not shown) on the lower surface (e.g., the bottom surface) CSb of the lower dielectric layer 400, and forming a second interface layer (not shown) on the upper surface (e.g., the top surface) of the peripheral substrate 10. A plasma treatment may be performed on surfaces of the first and second interface layers to remove a —CN group at a distal end of a SiCN layer and to form dangling bonds. A deionized water treatment may be performed on the surfaces of the first and second interface layers to form a —OH group on the dangling bond. The first and second interface layers may be in contact with each other and a thermocompression process may be performed. In the thermocompression process, —OH groups may combine with each other in H₂O shapes at interfaces between the first interface layer and the second interface layer, and a remaining —O— group and its surrounding Si may combine with each other to form a SiO₂ layer between the first interface layer and the second facial layer. Thus, the peripheral circuit structure PS may be bonded to the lower surface (e.g., the bottom surface) CSb of the lower dielectric layer 400, and the interface layer AL may be formed between the peripheral circuit structure PS and the lower surface (e.g., the bottom surface) CSb of the lower dielectric layer 400. The interface layer AL may include a triple-layered structure in which a SiCN layer, a SiO₂ layer, and a SiCN layer are sequentially stacked.

Although not shown, a dielectric layer (not shown) may be interposed between the peripheral substrate 10 and sidewalls of the peripheral through contacts 37. This configuration may insulate the peripheral through contacts 37 and the peripheral substrate 10 from each other. For example, as the dielectric layer (not shown) extending in (e.g., penetrating) the peripheral through contacts 37 are formed in advance on the peripheral substrate 10, it may be possible to reduce process failure and process burden compared with a case where the dielectric layer is formed to cover entire sidewalls of the peripheral through contacts 37.

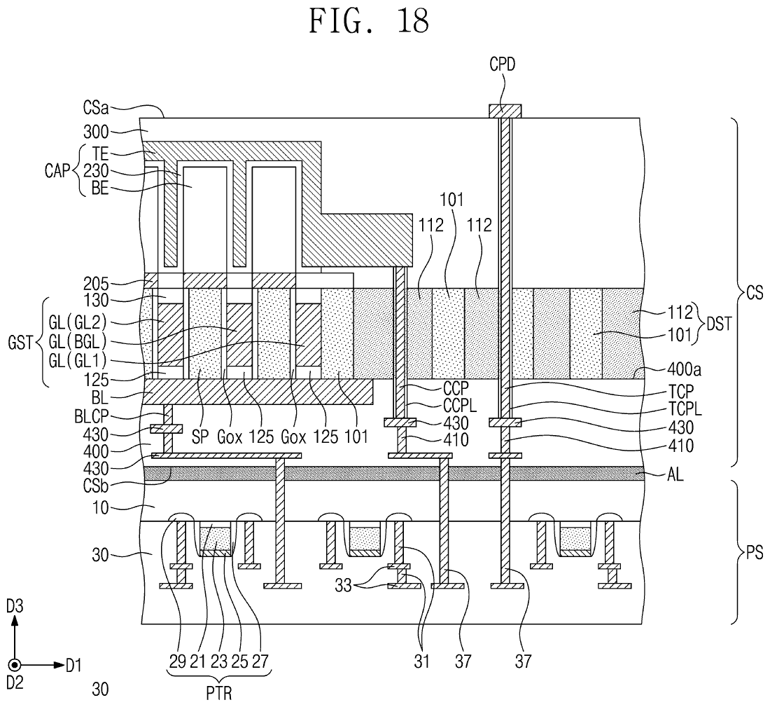

Referring to FIG. 18, according to some embodiments, a semiconductor device of FIG. 17 may further include a through plug line layer TCPL that (conformally) extends around (e.g., surrounds) a lateral surface (a side surface) of the through contact plug TCP and a capacitor plug line layer CCL that (conformally) extends around (e.g., surrounds) a lateral surface (a side surface) of the capacitor contact plug CCP. In this case, as discussed with reference to FIG. 16, a through plug line layer TCPL and a capacitor plug line layer CCL may be included for respectively insulating the through contact plug TCP and the capacitor contact plug CCP from the dummy substrate pattern 101.

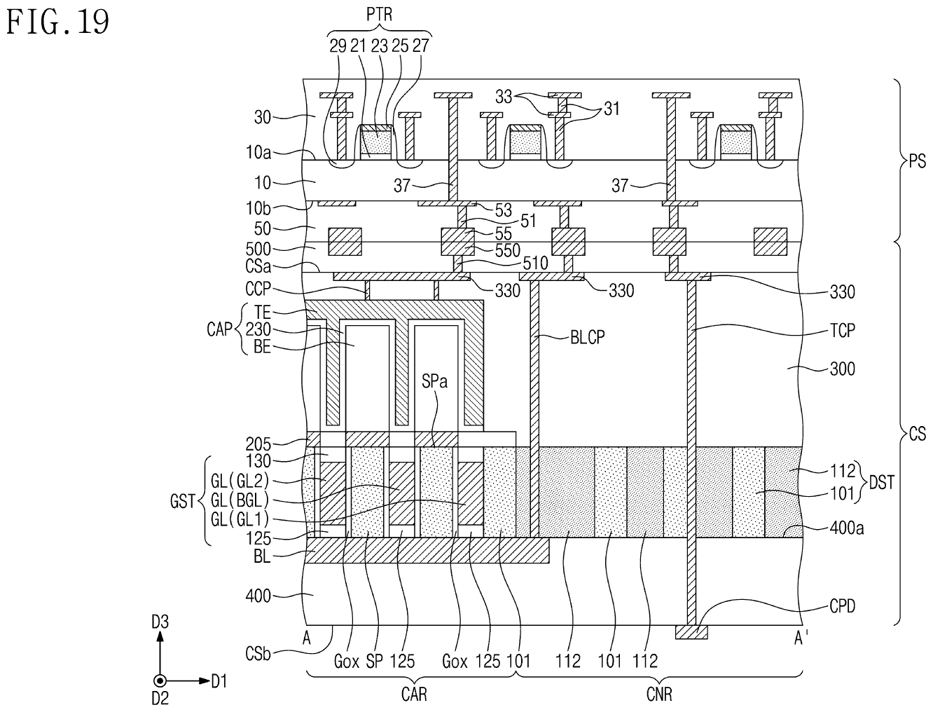

Referring to FIG. 19, according to some embodiments, a capacitor contact plug CCP may be disposed in the first upper dielectric layer 300. The capacitor contact plug CCP may be connected to the capacitor structure CAP. The capacitor contact plug CCP may be connected to upper circuit lines 330.

A bit-line contact plug BLCP may be disposed to extend in (e.g., penetrate) the dummy structure DST and a portion of the first upper dielectric layer 300. The bit-line contact plug BLCP may be connected to the bit line BL. The bit-line contact plug BLCP may be connected to the upper circuit lines 330.

A connection pad CPD may be disposed on the lower surface (e.g., the bottom surface) CSb of the lower dielectric layer 400. A through contact plug TCP may be disposed to extend in (e.g., penetrate) the lower dielectric layer 400, the dummy structure DST, and a portion of the first upper dielectric layer 300 to come into connection with the connection pad CPD. The through contact plug TCP may be connected to the upper circuit lines 330.

A second upper dielectric layer 500 may be disposed on the first upper dielectric layer 300. Upper contact plugs 510 and upper bonding pads 550 may be disposed in the second upper dielectric layer 500. An upper surface (e.g., a top surface) of the second upper dielectric layer 500 may not be on (may not cover) upper surfaces (e.g., top surfaces) of the upper bonding pads 550. The upper surface (e.g., the top surface) of the second upper dielectric layer 500 may be coplanar with the upper surfaces (e.g., the top surfaces) of the upper bonding pads 550. The capacitor contact plug CCP, the bit-line contact plug BLCP, and the through contact plug TCP may be electrically connected through the upper contact plugs 510 to the upper bonding pads 550.

The peripheral circuit structure PS may be disposed on the upper surface (e.g., the top surface) of the second upper dielectric layer 500. The peripheral circuit structure PS may include peripheral through contacts 37 electrically connected to the peripheral circuit transistors PTR through the peripheral contact plugs 31 and the peripheral circuit lines 33.

A second dielectric layer 50 may be disposed on a lower surface (e.g., a bottom surface) 10b of the peripheral substrate 10. The second dielectric layer 50 may include lower contact plugs 51, lower circuit lines 53, and lower bonding pads 55. A lower surface (e.g., a bottom surface) of the second dielectric layer 50 may not be on (may not cover) lower surfaces (e.g., bottom surfaces) of the lower bonding pads 55. The lower surface (e.g., the bottom surface) of the second dielectric layer 50 may be coplanar with the lower surfaces (e.g., the bottom surfaces) of the lower bonding pads 55. The peripheral through contacts 37 may extend in (e.g., penetrate) the peripheral substrate 10 to come into electrical connection with the lower bonding pads 55 through the lower contact plugs 51 and the lower circuit lines 53.

The lower surfaces (e.g., the bottom surfaces) of the lower bonding pads 55 may be correspondingly in (direct) contact with the upper surfaces (e.g., the top surfaces) of the upper bonding pads 550. The lower and upper bonding pads 55 and 550 may include, for example, metal, such as copper (Cu), tungsten (W), aluminum (Al), nickel (Ni), and/or tin (Sn). For example, the lower and upper bonding pads 55 and 550 may include copper (Cu). The lower bonding pad 55 and the upper bonding pad 550 may constitute a single unitary shape without any interface therebetween. Although the lower and upper bonding pads 55 and 550 are illustrated to have their sidewalls linearly aligned with each other (in the third direction D3), the present inventive concepts are not limited thereto, and when viewed in plan, the lower and upper bonding pads 55 and 550 may have their sidewalls spaced apart from each other.

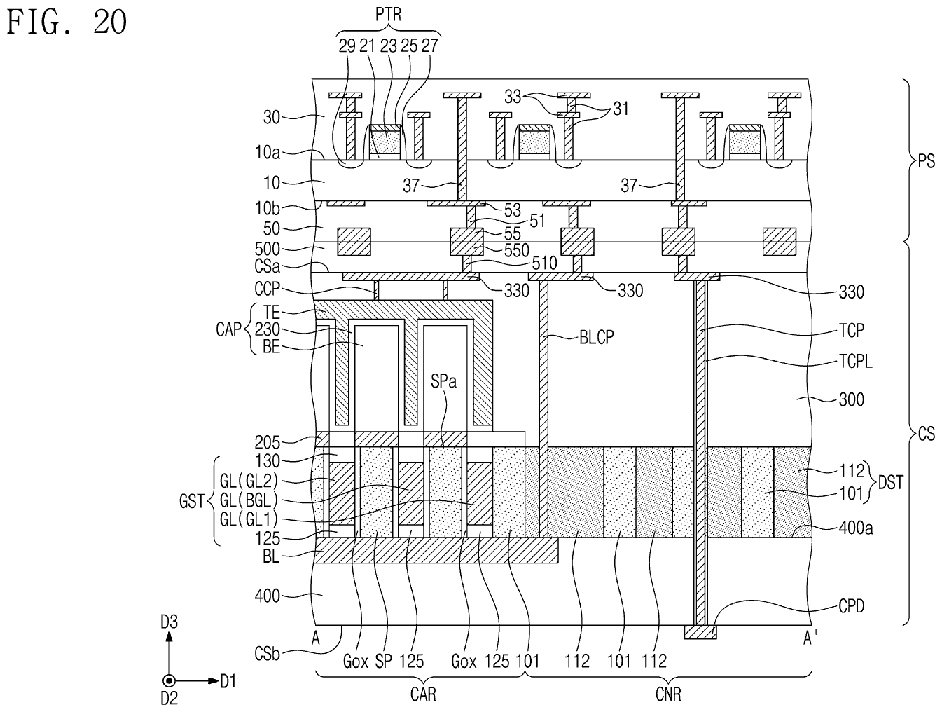

Referring to FIG. 20, a semiconductor device of FIG. 19 may further include a through plug line layer TCPL that (conformally) extends around (e.g., surrounds) a lateral surface (a side surface) of the through contact plug TCP. As discussed with reference to FIG. 16, the through plug line layer TCPL may be used for insulation between the dummy substrate pattern 101 and the through contact plug TCP.

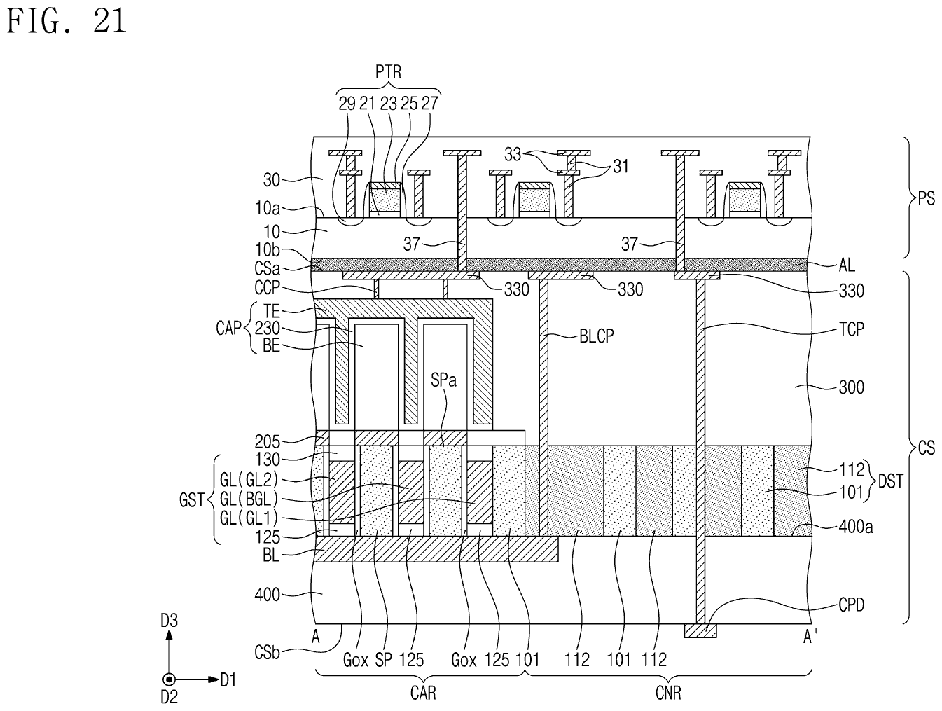

Referring to FIG. 21, according to some embodiments, an interface layer AL may be disposed on the first upper dielectric layer 300. The peripheral circuit structure PS may be disposed on the interface layer AL. As discussed with reference to FIG. 17, this case may reduce process failure and process burden compared with a case where a dielectric layer is formed to extend around (e.g., cover) (entire) sidewalls of the peripheral through contacts 37

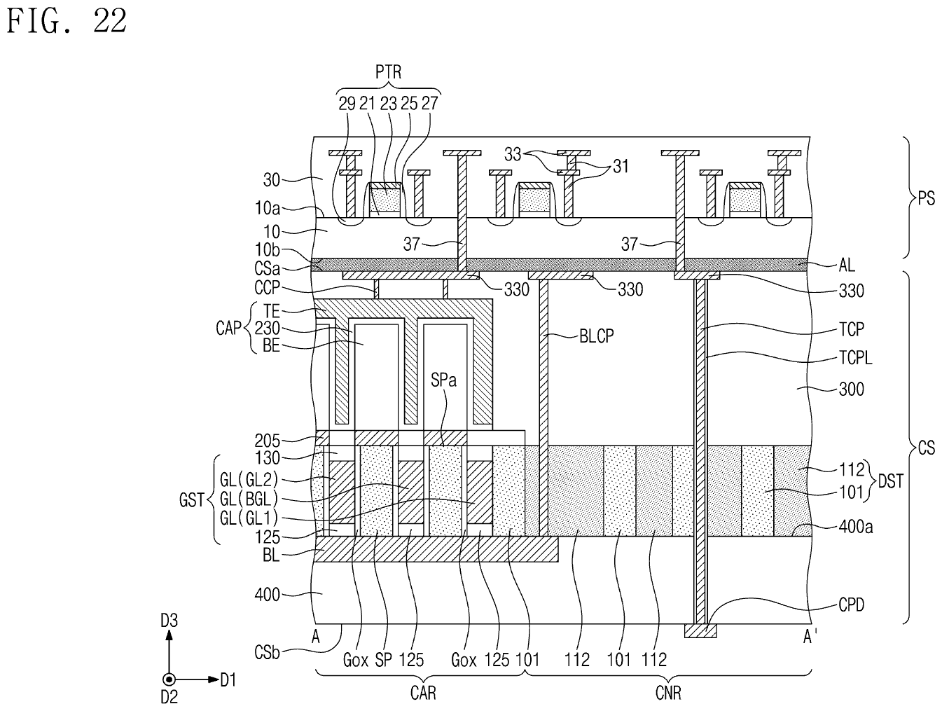

Referring to FIG. 22, according to some embodiments, a semiconductor device of FIG. 21 may further include a through plug line layer TCPL that (conformally) extends around (e.g., surrounds) a lateral surface (a side surface) of the through contact plug TCP. As discussed with reference to FIG. 16, the through plug line layer TCPL may be used for insulation between the dummy substrate pattern 101 and the through contact plug TCP.

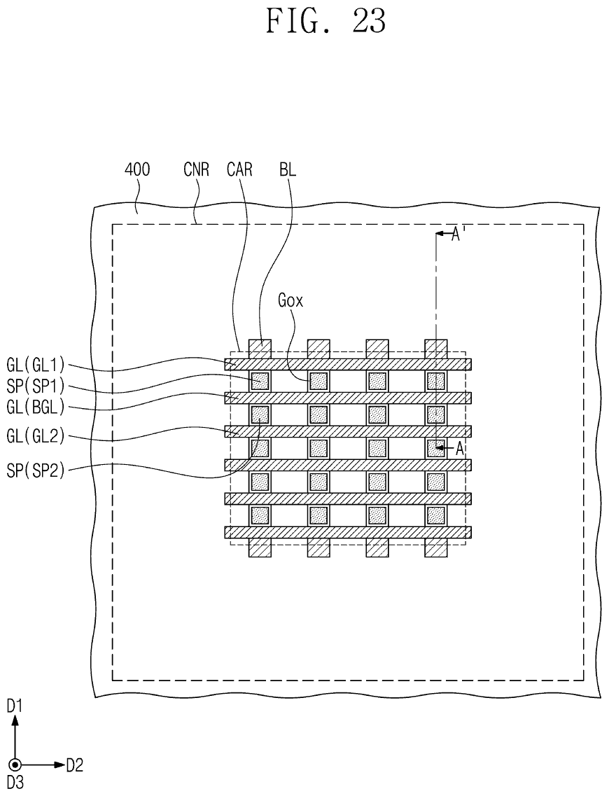

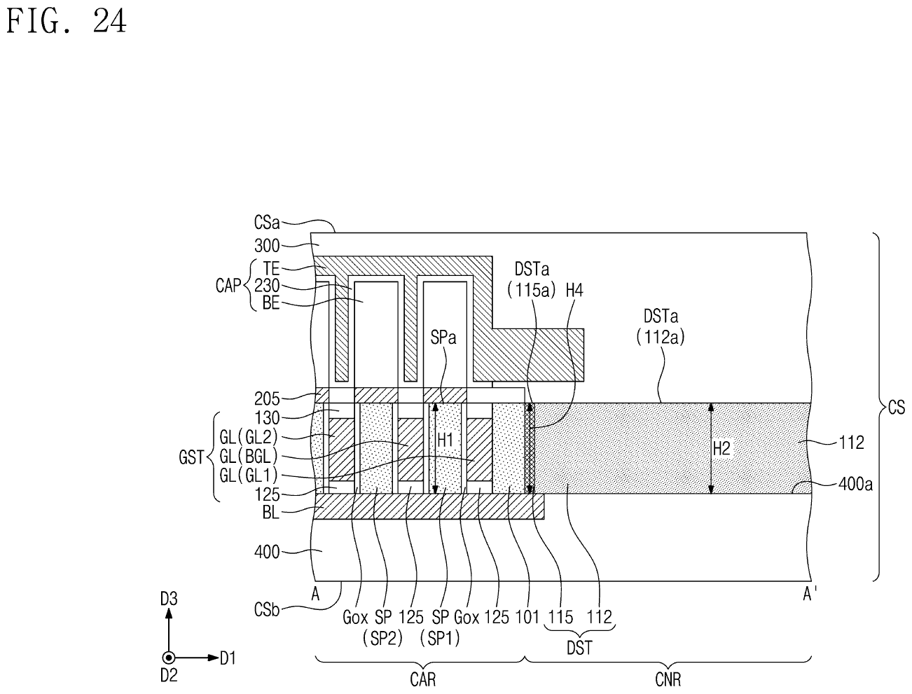

FIG. 23 illustrates a plan view showing a semiconductor device according to some embodiments of the present inventive concepts. FIG. 24 illustrates a cross-sectional view taken along line A-A′ of FIG. 23. For brevity of description, a repetitive explanation may be omitted.

Referring to FIGS. 23 and 24, the cell structure CS may be provided. A cell structure CS may include a lower dielectric layer 400. A dummy structure DST may be disposed on (in) the connection region CNR of the lower dielectric layer 400. An upper surface (e.g., a top surface) DSTa of the dummy structure DST may be coplanar with an upper surface (e.g., a top surface) SPa of the vertical channel pattern SP.

The dummy structure DST may include a peripheral dielectric layer 112 and a stop pattern 115 interposed between the peripheral dielectric layer 112 and the gate structure GST. For example, the stop pattern 115 may be interposed between the peripheral dielectric layer 112 and the dummy substrate pattern 101 disposed on one side of the first gate line GL1 (in the first direction D1). The stop pattern 115 may have a fourth thickness H4 in the vertical direction D3. The fourth thickness H4 of the stop pattern 115 may be the same as the first thickness H1 of the vertical channel pattern SP and the second thickness H2 of the peripheral dielectric layer 112. For example, the upper surface (e.g., the top surface) SPa of the vertical channel pattern SP may be coplanar with an upper surface (e.g., a top surface) 112a of the peripheral dielectric layer 112 and an upper surface (e.g., a top surface) 115a of the stop pattern 115.

The peripheral dielectric layer 112 may include a dielectric material, such as silicon oxide, silicon nitride, silicon oxynitride, and/or low-k dielectrics. The stop pattern 115 may include a dielectric material, such as silicon oxide, silicon nitride, silicon oxynitride, and/or low-k dielectrics. In some embodiments, the stop pattern 115 and the peripheral dielectric layer 112 include different materials. For example, the stop pattern 115 may not include the same material as that of the peripheral dielectric layer 112.

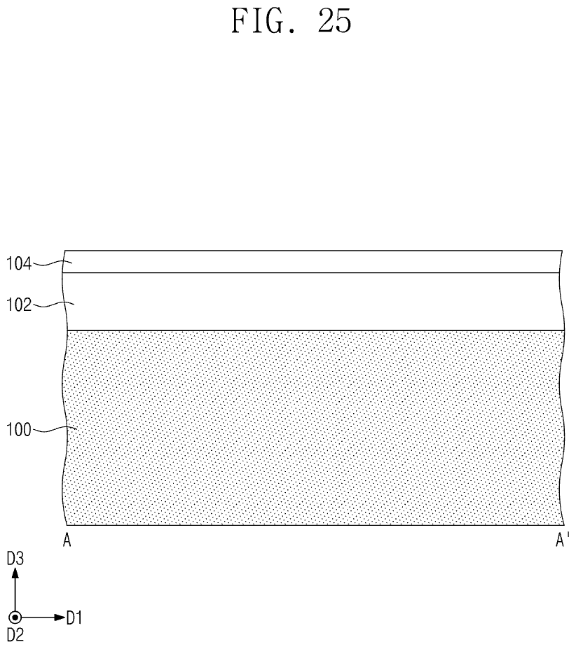

FIGS. 25 to 35 illustrate cross-sectional views taken along line A-A′ of FIG. 23, showing a method of fabricating a semiconductor device according to some embodiments of the present inventive concepts. For brevity of description, a repetitive explanation may be omitted.

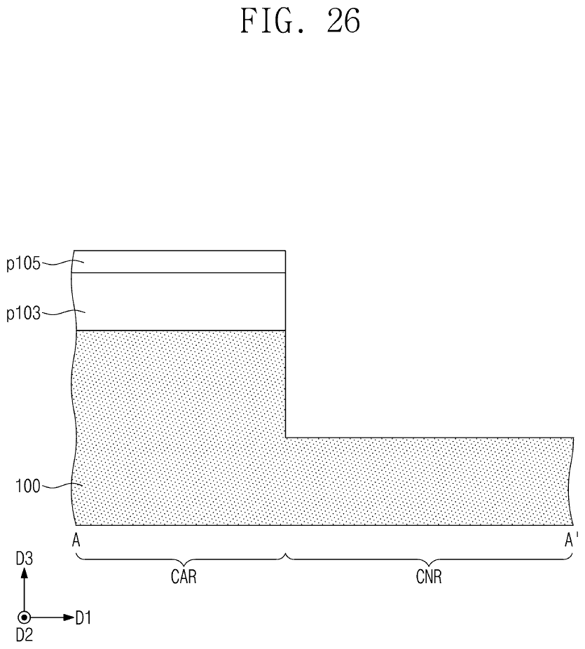

Referring to FIGS. 25 and 26, a substrate 100 may be provided. The substrate 100 may be a bare silicon wafer. A first sacrificial layer 102 and a second sacrificial layer 104 may be sequentially formed on the substrate 100. For example, the first sacrificial layer 102 may be disposed between the substrate 100 and the second sacrificial layer 104 in the third direction D3.

A preliminary first sacrificial pattern p103 and a preliminary second sacrificial pattern p105 may be formed on (in) a cell array region CAR of the substrate 100. The formation of the preliminary first sacrificial pattern p103 and the preliminary second sacrificial pattern p105 may include, for example, forming a mask pattern (not shown) on the second sacrificial layer 104, using the mask pattern as an etching mask to etch the second sacrificial layer 104, the first sacrificial layer 102, and an upper portion of the substrate 100 on (in) a connection region CNR, and removing the mask pattern.

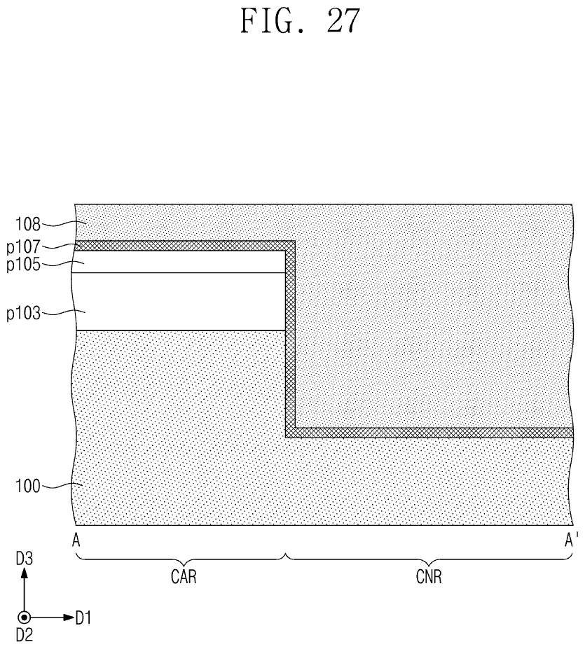

Referring to FIG. 27, a preliminary stop layer p107 may be formed. The preliminary stop layer p107 may be on (e.g., cover) an upper surface (e.g., a top surface) of the preliminary second sacrificial pattern p105, and may extend along lateral surfaces (e.g., side surfaces) of the preliminary second sacrificial pattern p105, the preliminary first sacrificial pattern p103, and the substrate 100 to thereby extend onto an upper surface (e.g., a top surface) of the substrate 100 (e.g., a remaining portion of the substrate 100 in the connection region CNR after the etching of the upper portion of the substrate 100 in the connection region CNR). The preliminary stop layer p107 may be formed by using a film formation technique (whose step coverage is excellent), such as chemical vapor deposition (CVD), physical vapor deposition (PVD), and/or atomic layer deposition (ALD).

A semiconductor layer 108 may be formed on the preliminary stop layer p107. The semiconductor layer 108 may (entirely) cover (overlap in the third direction D3) the cell array region CAR and the connection region CNR (of the substrate 100). The semiconductor layer 108 may include, for example, polycrystalline silicon. The semiconductor layer 108 may be formed by using a film formation technique, such as chemical vapor deposition (CVD) or physical vapor deposition (PVD).

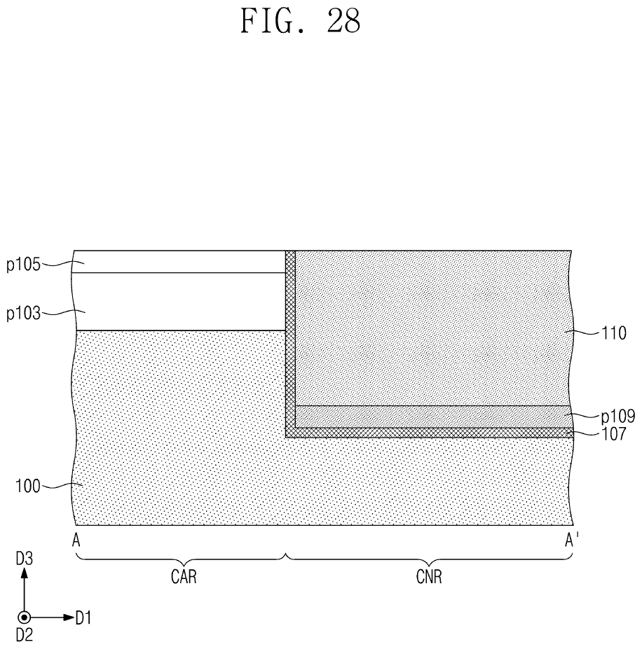

Referring to FIG. 28, a stop layer 107 may be formed. The formation of the stop layer 107 may include, for example, planarizing (e.g., removing or etching back) the semiconductor layer 108 and the preliminary stop layer p107 until the upper surface (e.g., the top surface) of the preliminary second sacrificial pattern p105 is exposed.

A semiconductor layer p109 may be formed on (in) the connection region CNR of the substrate 100 and on the stop layer 107. After the formation of the stop layer 107, the formation of the semiconductor layer p109 may include, for example, etching an upper portion of the semiconductor layer 108 on (in) the connection region CNR.

A separation dielectric layer 110 may be formed on (in) the connection region CNR of the substrate 100 and on the stop layer 107 and the semiconductor layer p109. An upper surface (e.g., a top surface) of the separation dielectric layer 110 may be coplanar with the upper surface (e.g., the top surface) of the preliminary second sacrificial pattern p105.

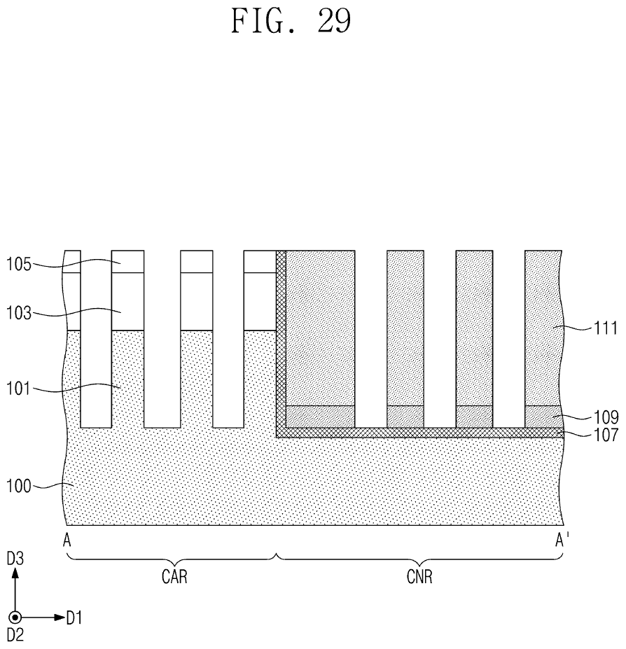

Referring to FIG. 29, dummy substrate patterns 101 may be formed on (in) the cell array region CAR of the substrate 100. First sacrificial patterns 103 and second sacrificial patterns 105 may be formed on the dummy substrate patterns 101. The formation of the dummy substrate patterns 101, the first sacrificial patterns 103, and the second sacrificial patterns 105 may be (substantially) the same as that discussed with reference to FIG. 7.

A semiconductor pattern 109 and a preliminary peripheral dielectric layer 111 may be formed on (in) the connection region CNR of the substrate 100. The formation of the semiconductor pattern 109 and the preliminary peripheral dielectric layer 111 may include, for example, forming a mask pattern (not shown) on the separation dielectric layer 110, using the mask pattern as an etching mask to pattern the separation dielectric layer 110 and the semiconductor layer p109, and removing the mask pattern. The patterning may be performed through an anisotropic etching process.

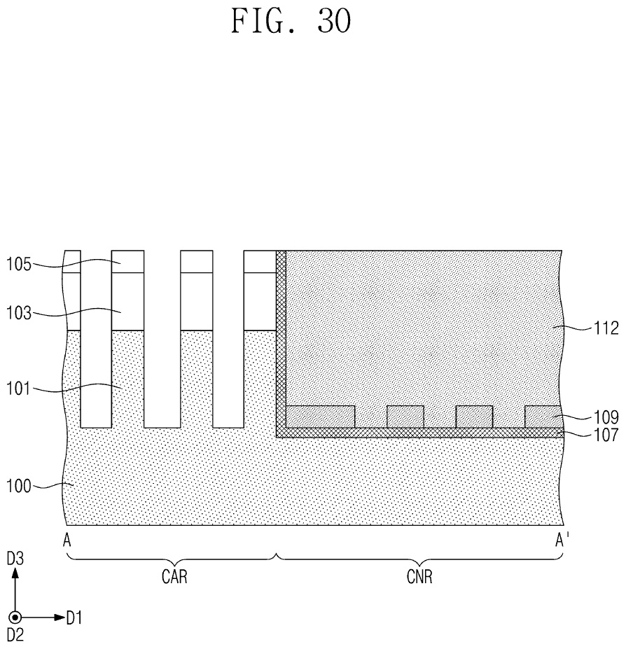

Referring to FIG. 30, a peripheral dielectric layer 112 may be formed on (in) the connection region CNR of the substrate 100. The formation of the peripheral dielectric layer 112 may include depositing an additional dielectric layer to fill a space between the semiconductor pattern 109 and the preliminary peripheral dielectric layer 111. In some embodiments, the additional dielectric layer may be disposed (may fill spaces) between the semiconductor patterns 109. In some embodiments, the additional dielectric layer may be disposed (may fill spaces) between the preliminary peripheral dielectric layers 111. The additional dielectric layer and the preliminary peripheral dielectric layer 111 may be called together the peripheral dielectric layer 112. In some embodiments, the additional dielectric layer and the preliminary peripheral dielectric layer 111 may include (e.g., may be) the same material.

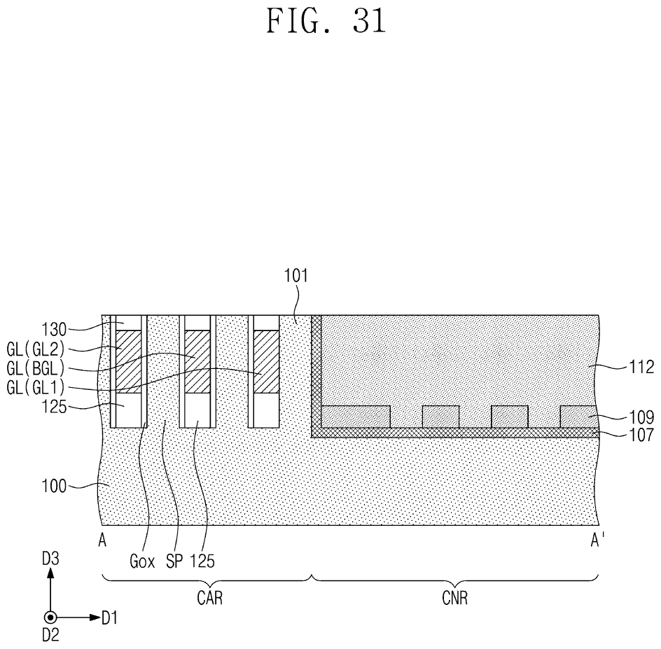

Referring to FIG. 31, there may be formed first buried layers 125, second buried layers 130, gate lines GL, a gate dielectric layer Gox, vertical channel patterns SP, and a dielectric pattern 120. This step may be achieved by (substantially) the same method as that discussed with reference to FIGS. 10A and 10B.

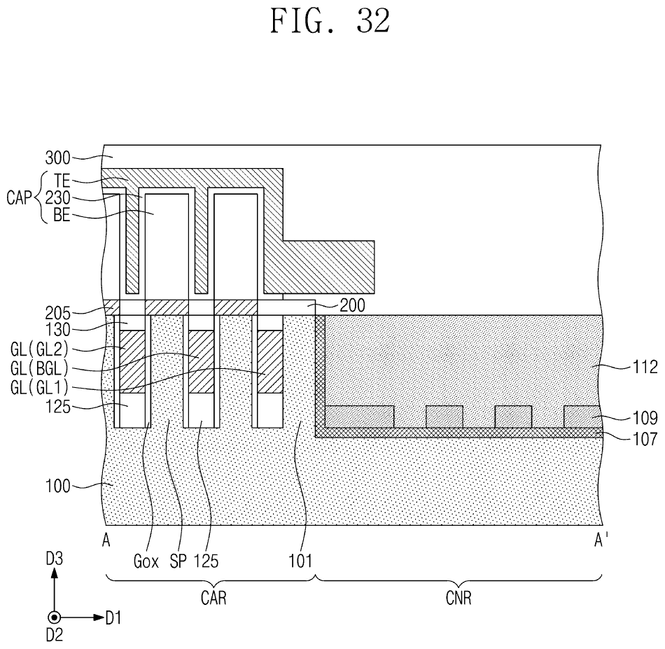

Referring to FIG. 32, there may be formed an interlayer dielectric layer 200, a capacitor contact 205, a capacitor structure CAP, and a first upper dielectric layer 300. This step may be achieved by (substantially) the same method as that discussed with reference to FIGS. 11A to 12B.

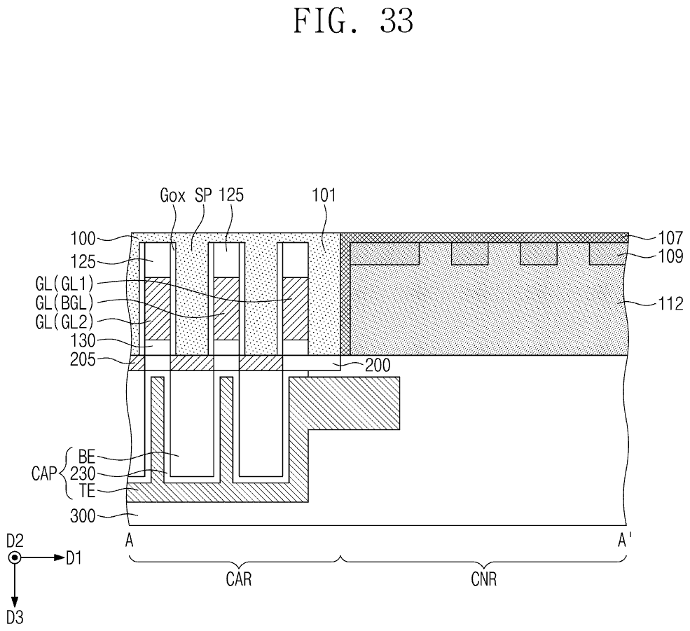

Referring to FIG. 33, a resultant structure of FIG. 32 may be turned upside down. For example, the resultant structure may be overturned to allow the first upper dielectric layer 300 to face downwards and the substrate 100 to face upwards. After the resultant structure is overturned, a portion of the substrate 100 may be removed. The partial removal of the substrate 100 may include, for example, performing a planarization process until an upper surface (e.g., a top surface) of the stop layer 107 on (in) the connection region CNR is exposed. The planarization process may include, for example, a chemical mechanical polishing (CMP) process and/or an etch-back process.

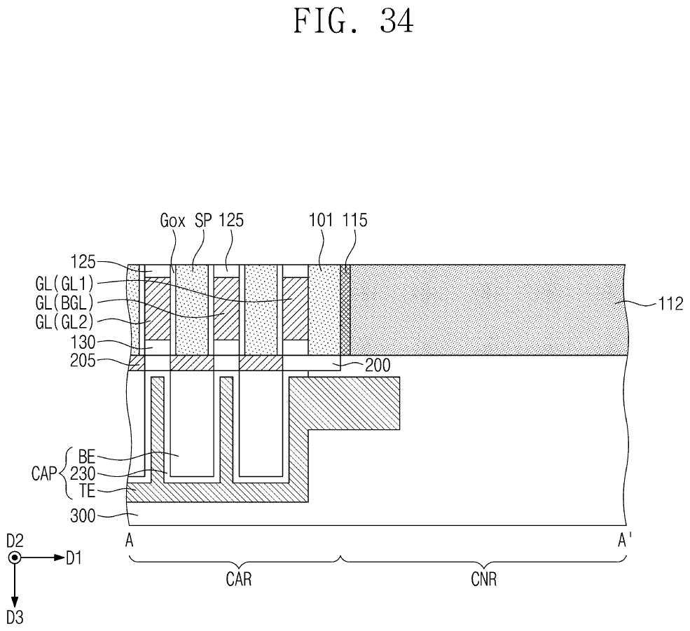

Referring to FIG. 34, a stop pattern 115 may be formed. The formation of the stop pattern 115 may be achieved through a patterning process. For example, the planarization process may be performed until the semiconductor pattern 109 is all removed on (in) the connection region CNR.

According to the present inventive concepts, a pattern density of the vertical channel patterns SP on (in) the cell array region CAR may be similar to (or same as) a pattern density of the semiconductor pattern 109 on (in) the connection region CNR. Therefore, a dishing phenomenon may be prevented during the planarization process, and a semiconductor device may improve in reliability and electrical characteristics.

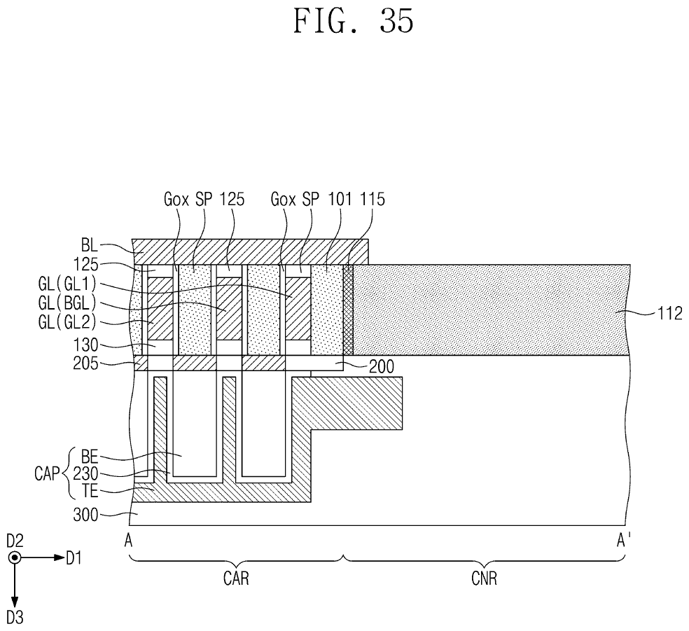

Referring to FIG. 35, a bit line BL may be formed. The bit line BL may be formed by (substantially) the same method as that discussed with reference to FIGS. 14A and 14B.

Referring back to FIG. 24, a lower dielectric layer 400 may be formed to (entirely) cover (e.g., overlap in the third direction D3) the cell array region CAR and the connection region CNR.

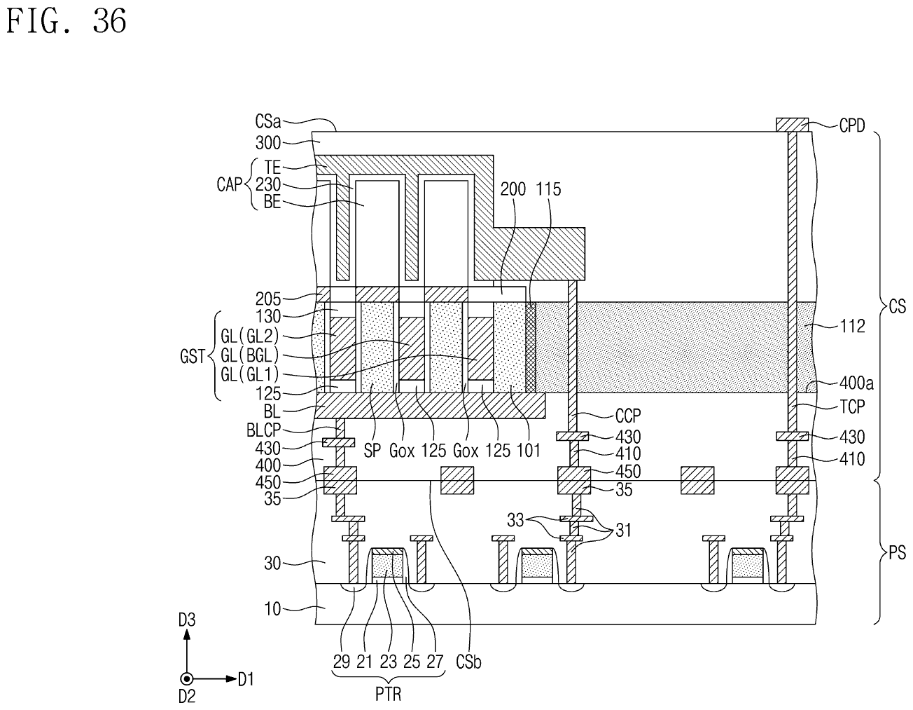

FIGS. 36 to 39 illustrate cross-sectional views showing a semiconductor device according to some embodiments of the present inventive concepts. For brevity of description, a repetitive explanation may be omitted.

Referring to FIG. 36, according to some embodiments, a peripheral dielectric layer 112 may be provided on the lower dielectric layer 400, and a stop pattern 115 may be interposed between the peripheral dielectric layer 112 and the gate structure GST (in the first direction D1). For example, the stop pattern 115 may be interposed between the peripheral dielectric layer 112 and the dummy substrate pattern 101 disposed on one side of the first gate line GL1 (in the first direction D1).

The lower dielectric layer 400 may be provided therein with a bit-line contact plug BLCP, connection circuit lines 430, and connection contact plugs 410. The bit-line contact plug BLCP, the connection circuit lines 430, and the connection contact plugs 410 may be (substantially) the same as those discussed with reference to FIG. 15.

A capacitor contact plug CCP may be disposed to extend in (e.g., penetrate) the dummy structure DST, (a portion of) the lower dielectric layer 400, and a portion of the first upper dielectric layer 300. The capacitor contact plug CCP may be (substantially) the same as that discussed with reference to FIG. 15.

A connection pad CPD may be disposed on the first upper dielectric layer 300. A through contact plug TCP may be disposed to extend in (e.g., penetrate) the first upper dielectric layer 300, the dummy structure DST, and a portion of the lower dielectric layer 400. The through contact plug TCP may be (substantially) the same as that discussed with reference to FIG. 15.

First bonding pads 450 may be disposed to electrically connect with the bit-line contact plug BLCP, the capacitor contact plug CCP, and the through contact plug TCP. The first bonding pads 450 may be (substantially) the same as that discussed with reference to FIG. 15.

A peripheral circuit structure PS may be disposed on the lower surface (e.g., the bottom surface) CSb of the lower dielectric layer 400. The peripheral circuit structure PS may be (substantially) the same as that discussed with reference to FIG. 15.

The lower surfaces (e.g., the bottom surfaces) of the first bonding pads 450 may correspondingly be in (direct) contact with the upper surfaces (e.g., the top surfaces) of the second bonding pads 35. The first bonding pad 450 and the second bonding pad 35 may constitute a single unitary shape without any interface therebetween.

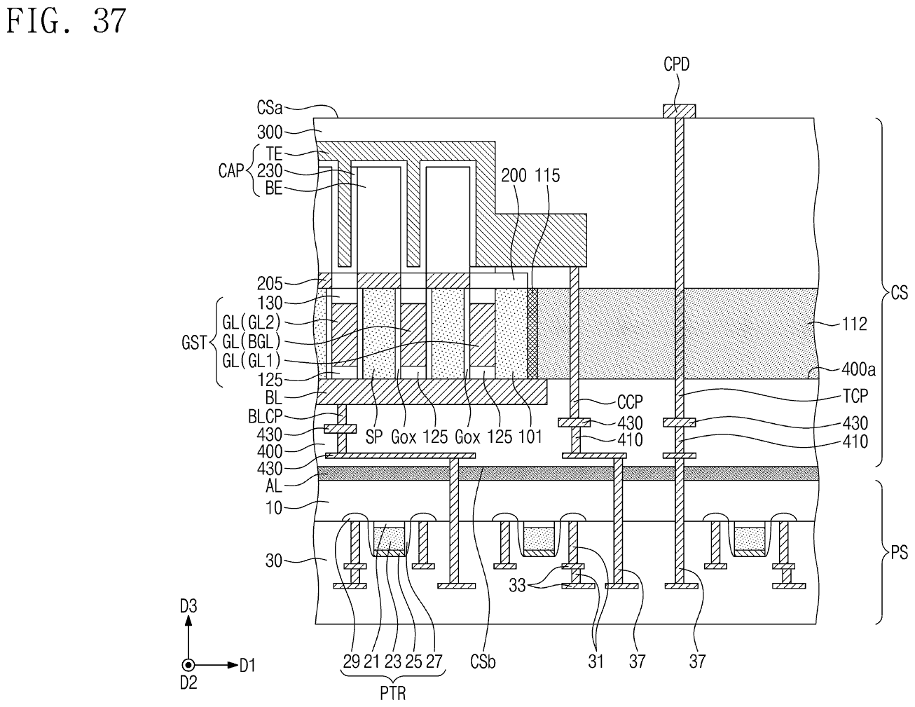

Referring to FIG. 37, according to some embodiments, a peripheral dielectric layer 112 may be provided on (the upper surface 400a of) the lower dielectric layer 400, and a stop pattern 115 may be interposed between the peripheral dielectric layer 112 and the gate structure GST (in the first direction D1). An interface layer AL may be disposed on the lower surface (e.g., the bottom surface) CSb of the lower dielectric layer 400. A peripheral circuit structure PS may be disposed on a lower surface (e.g., a bottom surface) of the interface layer AL. The interface layer AL may be (substantially) the same as that discussed with reference to FIG. 17. As discussed with reference to FIG. 17, this case may reduce process failure and process burden compared with a case where a dielectric layer is formed to cover entire sidewalls of the peripheral through contacts 37

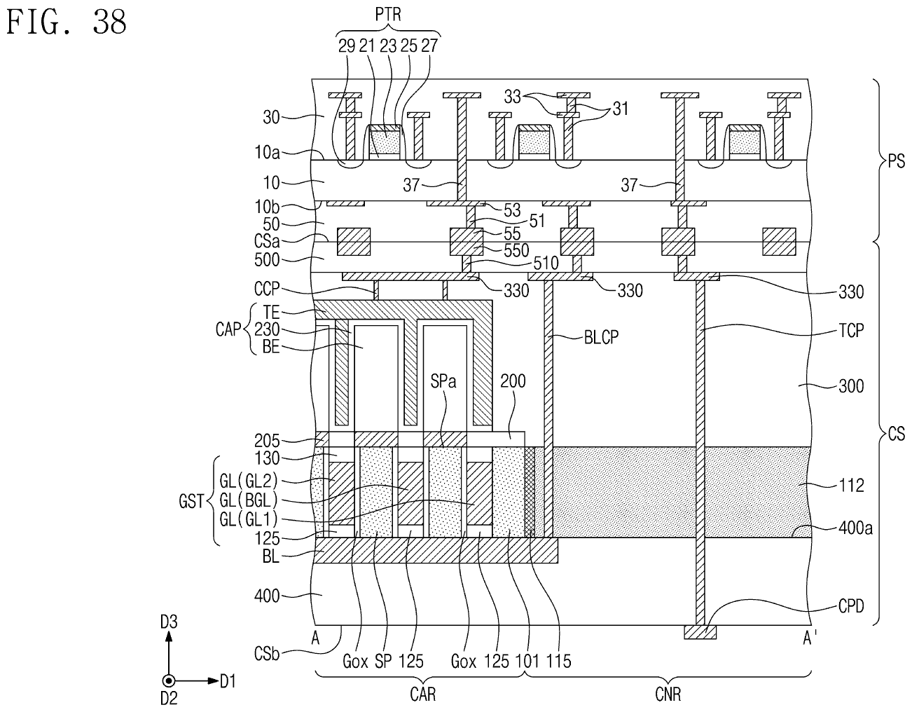

Referring to FIG. 38, according to some embodiments, a peripheral dielectric layer 112 may be provided on (an upper surface 400a of) the lower dielectric layer 400, and a stop pattern 115 may be interposed between the peripheral dielectric layer 112 and the gate structure GST (in the first direction D1). A second upper dielectric layer 500 may be disposed on (an upper surface of) the first upper dielectric layer 300. A peripheral circuit structure PS may be disposed on an (upper surface) a top surface CSa of the second upper dielectric layer 500. The first upper dielectric layer 300, the second upper dielectric layer 500, and components included in the peripheral circuit structure PS may be (substantially) the same as those discussed with reference to FIG. 19.

The lower surfaces (e.g., bottom surfaces) of the lower bonding pads 55 may correspondingly be in (direct) contact with the upper surfaces (e.g., the top surfaces) of the upper bonding pads 550. The lower bonding pad 55 and the upper bonding pad 550 may constitute a single unitary shape without any interface therebetween.

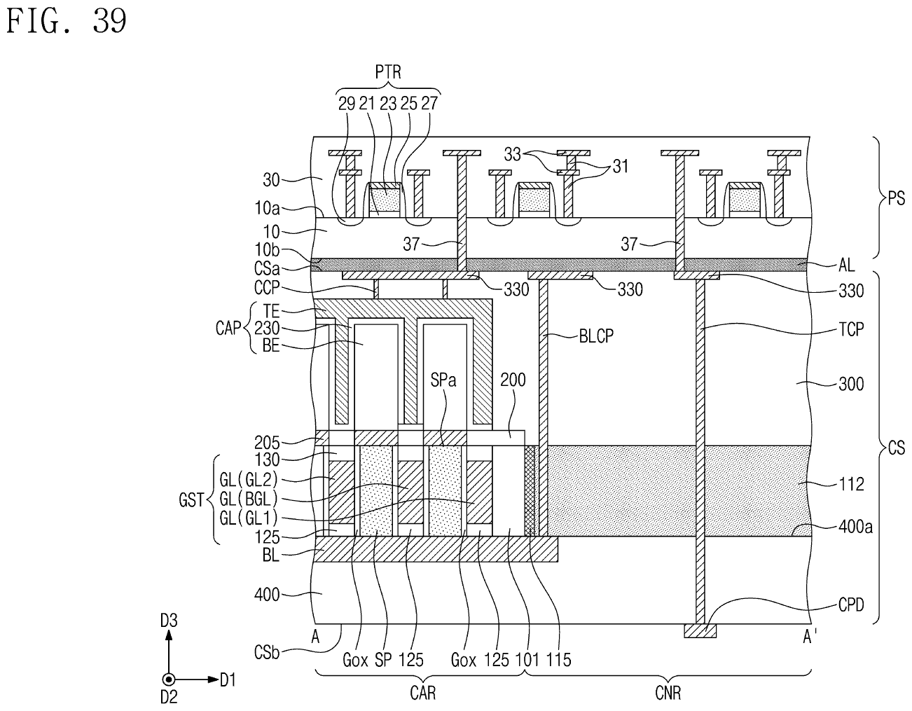

Referring to FIG. 39, according to some embodiments, a peripheral dielectric layer 112 may be provided on (the upper surface 400a of) the lower dielectric layer 400, and a stop pattern 115 may be interposed between the peripheral dielectric layer 112 and the gate structure GST (in the first direction D1). An interface layer AL may be disposed on (the upper surface CSa of) the first upper dielectric layer 300. A peripheral circuit structure PS may be disposed on (the upper surface of) the interface layer AL. The interface layer AL may be (substantially) the same as that discussed with reference to FIG. 17. As discussed with reference to FIG. 17, this case may reduce process failure and process burden compared with a case where a dielectric layer is formed to cover entire sidewalls of the peripheral through contacts 37

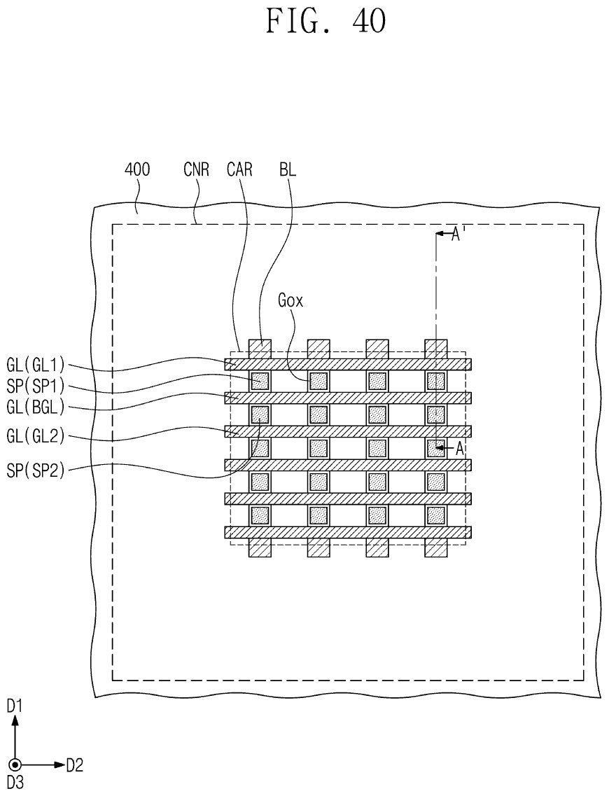

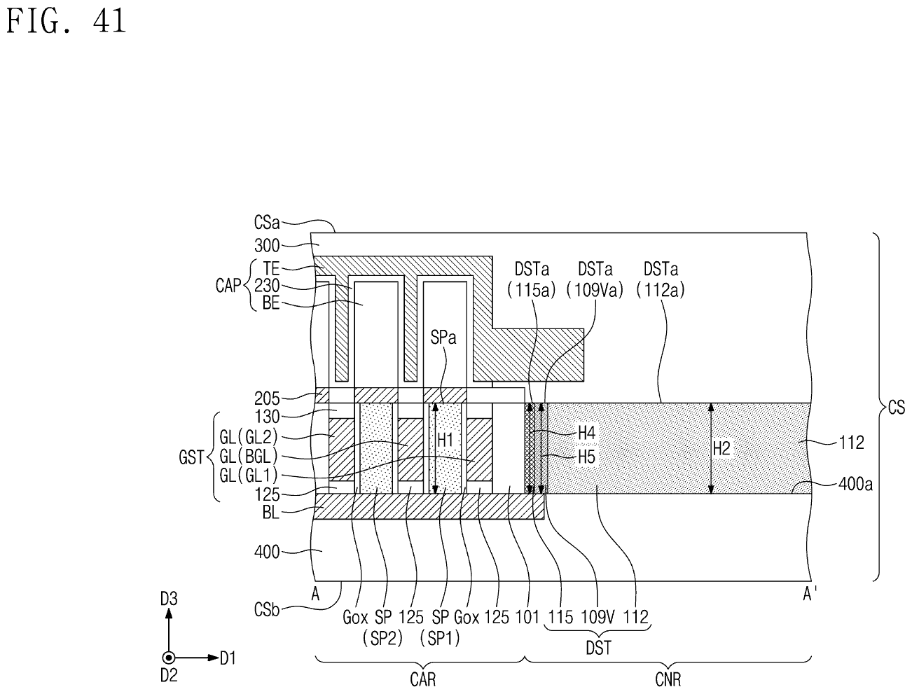

FIG. 40 illustrates a plan view showing a semiconductor device according to some embodiments of the present inventive concepts. FIG. 41 illustrates a cross-sectional view taken along line A-A′ of FIG. 40. For brevity of description, a repetitive explanation may be omitted.

Referring to FIGS. 40 and 41, a cell structure CS may be provided. The cell structure CS may include a lower dielectric layer 400. A dummy structure DST may be disposed on (in) the connection region CNR of the lower dielectric layer 400. An upper surface (e.g., a top surface) DSTa of the dummy structure DST may be coplanar with an upper surface (e.g., a top surface) SPa of the vertical channel pattern SP.

The dummy structure DST may include a peripheral dielectric layer 112 and a stop pattern 115 interposed between the peripheral dielectric layer 112 and the gate structure GST (in the first direction D1). For example, the stop pattern 115 may be interposed between the peripheral dielectric layer 112 and the dummy substrate pattern 101 disposed on one side of the first gate line GL1 (in the first direction D1). The stop pattern 115 may have a fourth thickness H4 in the vertical direction D3.

The dummy structure DST may further include a vertical part 109V of a semiconductor pattern (109), which vertical part 109V of the semiconductor pattern (109) is interposed between the stop pattern 115 and the peripheral dielectric layer 112. The vertical part 109V of the semiconductor pattern (109) may have a fifth thickness H5 in the vertical direction D3. The fifth thickness H5 of the semiconductor pattern may be the equal to the first thickness H1 of the vertical channel pattern SP, the second thickness H2 of the peripheral dielectric layer 112, and the fourth thickness H4 of the stop pattern 115. For example, the upper surface (e.g., the top surface) SPa of the vertical channel pattern SP may be coplanar with an upper surface (e.g., a top surface) 112a of the peripheral dielectric layer 112, an upper surface (e.g., a top surface) 115a of the stop pattern 115, and an upper surface (e.g., a top surface) 109Va of the vertical part 109V of the semiconductor pattern (109).

The vertical part 109V of the semiconductor pattern (109) may include, for example, polycrystalline silicon.

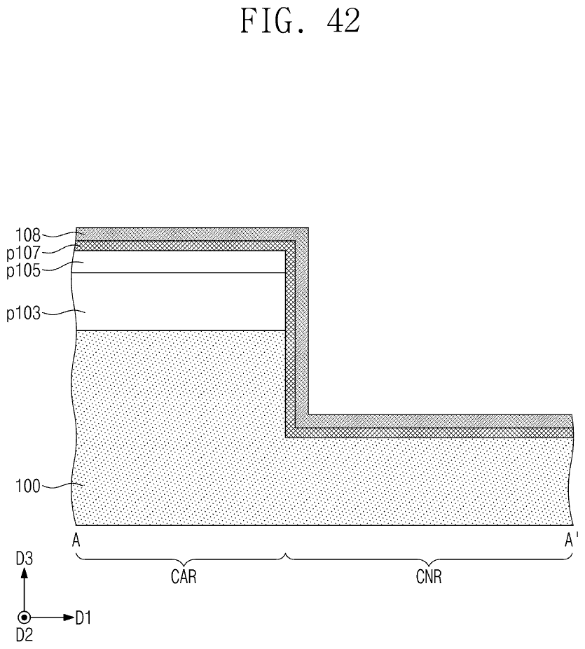

FIGS. 42 to 47 illustrate cross-sectional views taken along line A-A′ of FIG. 40, showing a method of fabricating a semiconductor device according to some embodiments of the present inventive concepts. For brevity of description, a repetitive explanation may be omitted.

Referring to FIG. 42, a substrate 100 may be provided. The substrate 100 may be a bare silicon wafer.

A preliminary first sacrificial pattern p103 and a preliminary second sacrificial pattern p105 may be formed on (in) a cell array region CAR of the substrate 100. The preliminary first sacrificial pattern p 103 may be disposed between the preliminary second sacrificial pattern p105 and the substrate 100 in the third direction D3. The preliminary first sacrificial pattern p103 and the preliminary second sacrificial pattern p105 may be formed by (substantially) the same method as that discussed with reference to FIGS. 25 and 26.

A preliminary stop layer p107 may be formed. The preliminary stop layer p107 may be on (e.g., cover) an upper surface (e.g., a top surface) of the preliminary second sacrificial pattern p105, and may extend along side surfaces (e.g., lateral surfaces) of the preliminary second sacrificial pattern p105, the preliminary first sacrificial pattern p103, and the substrate 100 to thereby extend onto an upper surface (e.g., a top surface) of the substrate 100.

A semiconductor layer 108 may be formed on the preliminary stop layer p107. The semiconductor layer 108 may (conformally) cover upper surfaces (e.g., top surfaces) and a side surface (e.g., a lateral surface) of the preliminary stop layer p107. The semiconductor layer 108 may be formed by using a film formation technique (whose step coverage is excellent), such as chemical vapor deposition (CVD), physical vapor deposition (PVD), and/or atomic layer deposition (ALD). The semiconductor layer 108 may include, for example, polycrystalline silicon.

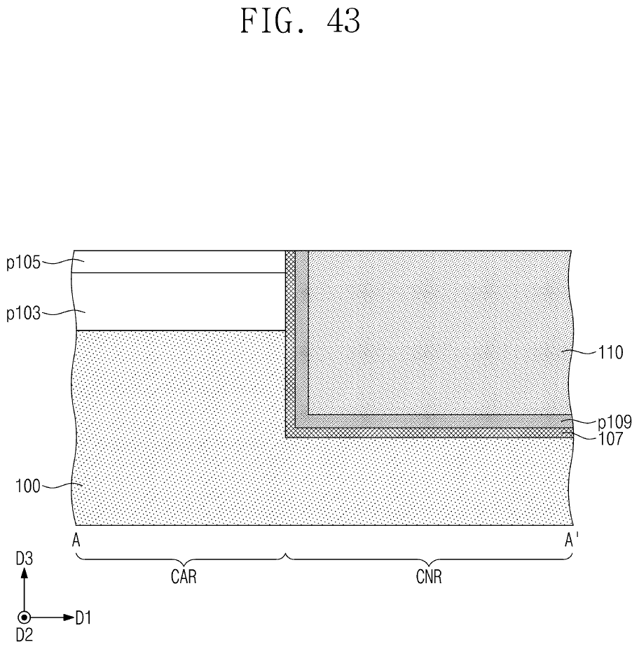

Referring to FIG. 43, a stop layer 107 and a semiconductor layer p109 may be formed. The formation of the stop layer 107 and the semiconductor layer p109 may include, for example, planarizing a portion of the semiconductor layer 108 and a portion of the preliminary stop layer p107 until the upper surface (e.g., the top surface) of the preliminary second sacrificial pattern p105 is exposed.

A separation dielectric layer 110 may be formed on (in) the connection region CNR of the substrate 100 and on the semiconductor layer p109. An upper surface (e.g., a top surface) of the separation dielectric layer 110 may be coplanar with the upper surface (e.g., the top surface) of the preliminary second sacrificial pattern p105.

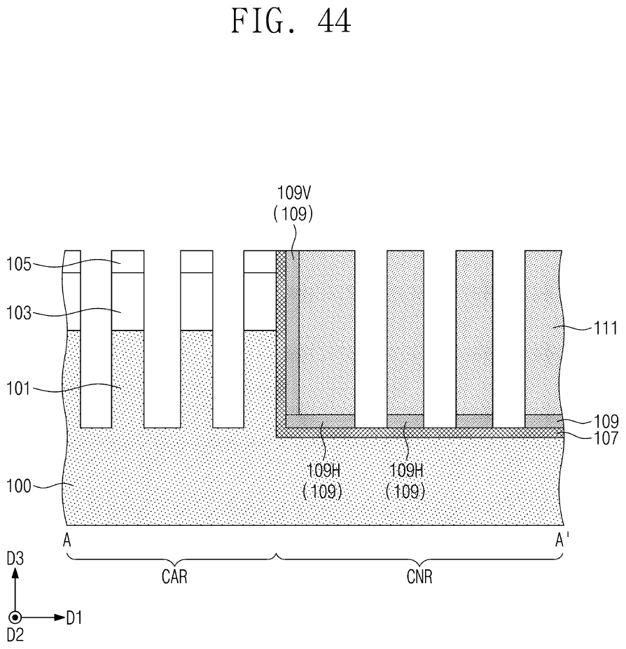

Referring to FIG. 44, dummy substrate patterns 101 may be formed on (in) the cell array region CAR of the substrate 100. First sacrificial patterns 103 and second sacrificial patterns 105 may be formed on the dummy substrate patterns 101. The formation of the dummy substrate patterns 101, the first sacrificial patterns 103, and the second sacrificial patterns 105 may be (substantially) the same as that discussed with reference to FIG. 7.

A semiconductor pattern 109 and a preliminary peripheral dielectric layer 111 may be formed on (in) the connection region CNR of the substrate 100. The semiconductor pattern 109 and the preliminary peripheral dielectric layer 111 may be formed by (substantially) the same method as that discussed with reference to FIG. 29.

The semiconductor pattern 109 may include a horizontal part 109H and a vertical part 109V. The horizontal part 109H of the semiconductor pattern 109 may be a portion in contact with an upper surface (e.g., a top surface) of the stop layer 107. The vertical part 109V of the semiconductor pattern 109 may have a shape that extends in the vertical direction D3 while being in contact with a side surface (e.g., a lateral surface) of the stop layer 107. For example, the horizontal part 109H of the semiconductor pattern 109 may be disposed between the preliminary peripheral dielectric layer 111 and the stop layer 107 in the third direction D3 and/or between the the vertical part 109V of the semiconductor pattern 109 and the stop layer 107 in the third direction D3. In some embodiments, the vertical part 109V of the semiconductor pattern 109 may be disposed between the preliminary peripheral dielectric layer 111 and the stop layer 107 in the first direction D1.

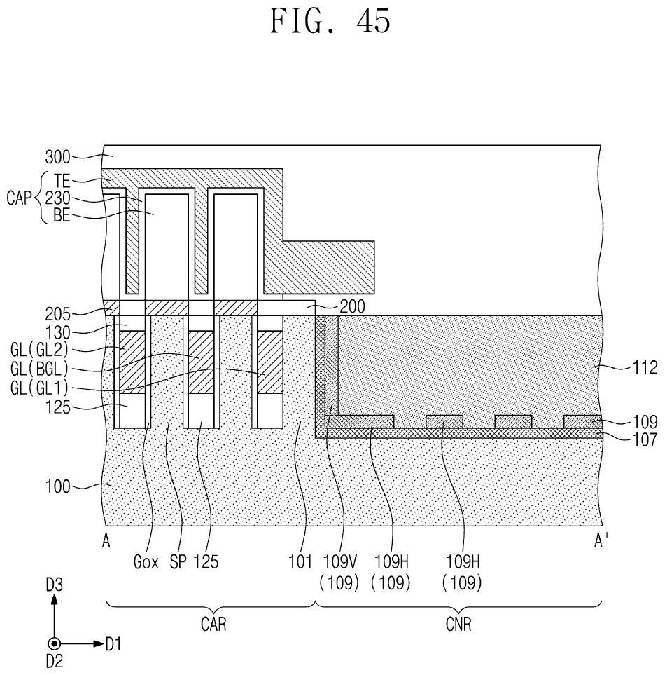

Referring to FIG. 45, there may be formed a peripheral dielectric layer 112, first buried layers 125, second buried layers 130, gate lines GL, a gate dielectric layer Gox, vertical channel patterns SP, and a dielectric pattern 120. This step may be achieved by (substantially) the same method as that discussed with reference to FIGS. 10A and 10B.

There may be formed an interlayer dielectric layer 200, a capacitor contact 205, and a first upper dielectric layer 300. This step may be achieved by (substantially) the same method as that discussed with reference to FIGS. 11A to 12B.

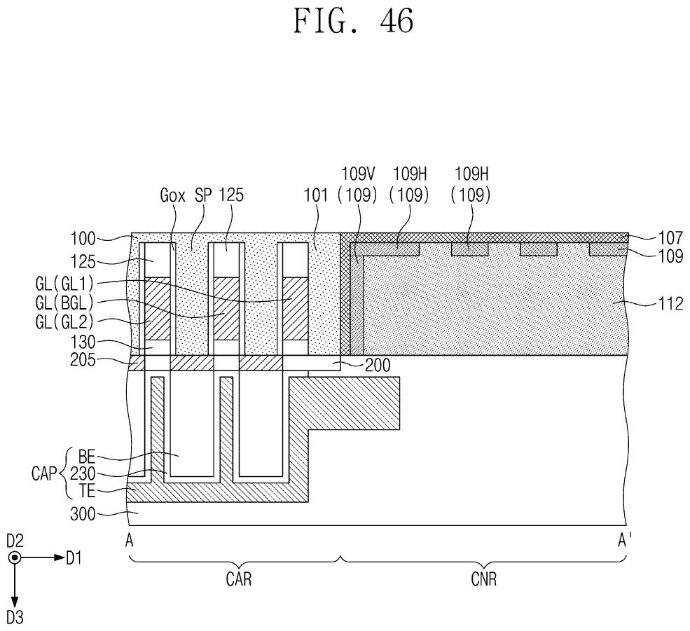

Referring to FIG. 46, a resultant structure of FIG. 45 may be turned upside down. For example, the resultant structure may be overturned to allow the first upper dielectric layer 300 to face downwards and the substrate 100 to face upwards. After the resultant structure is overturned, a portion of the substrate 100 may be removed. The partial removal of the substrate 100 may include, for example, performing a planarization process until the upper surface (e.g., the top surface) of the stop layer 107 on (in) the connection region CNR is exposed. The planarization process may include, for example, a chemical mechanical polishing (CMP) process or an etch-back process.

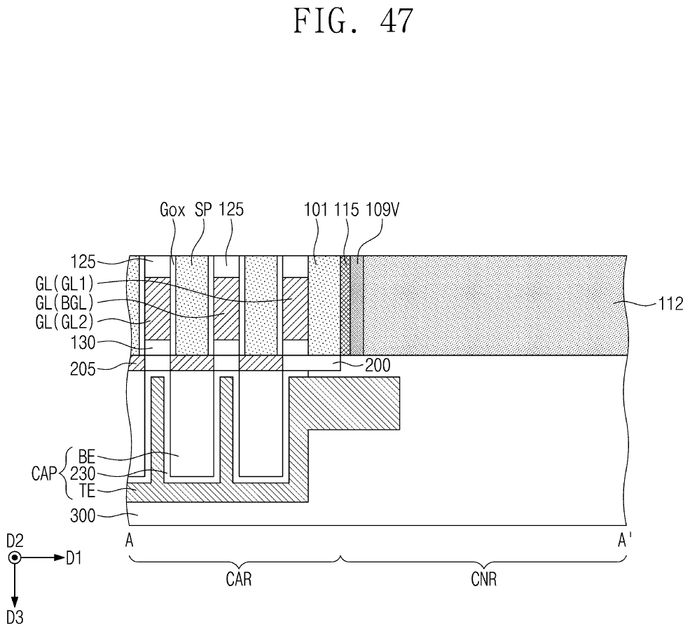

Referring to FIG. 47, a stop pattern 115 may be formed. The formation of the stop pattern 115 may include performing a planarization process until the horizontal part 109H of the semiconductor pattern 109 is all removed on (in) the connection region CNR. After the planarization process, (at least a portion of) the vertical part 109V of the semiconductor pattern 109 may remain.

According to the present inventive concepts, a pattern density of the vertical channel patterns SP on (in) the cell array region CAR may be similar to (or equal to) a pattern density of the semiconductor pattern 109 on (in) the connection region CNR. Therefore, a dishing phenomenon may be reduced (e.g., prevented) during the planarization process, and a semiconductor device may improve in reliability and electrical characteristics.

Referring back to FIG. 41, a bit line BL may be formed. The bit line BL may be formed by (substantially) the same method as that discussed with reference to FIGS. 14A and 14B. A lower dielectric layer 400 may be formed to entirely cover (e.g., overlap in the third direction D3) the cell array region CAR and the connection region CNR.

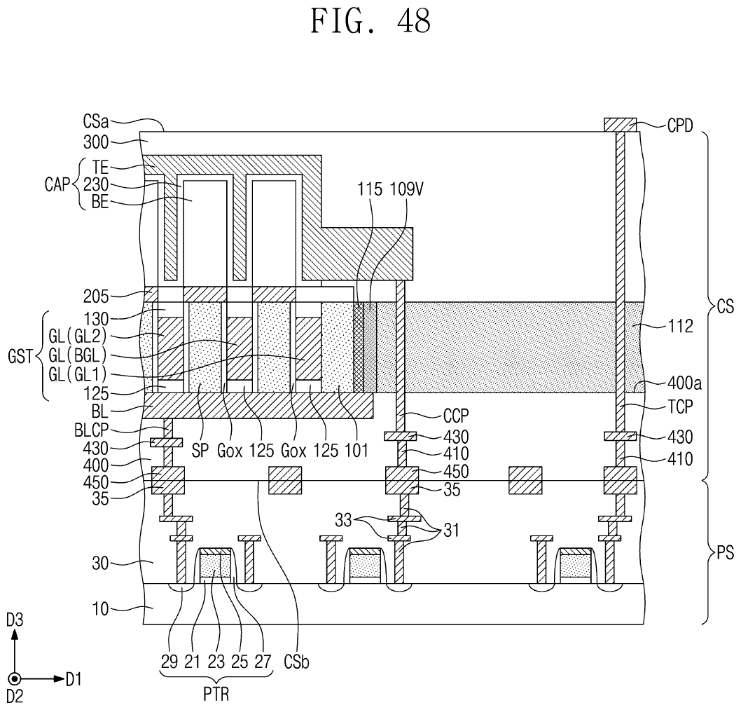

FIGS. 48 to 51 illustrate cross-sectional views showing a semiconductor device according to some embodiments of the present inventive concepts. For brevity of description, a repetitive explanation may be omitted.

Referring to FIG. 48, according to some embodiments, the dummy structure DST may further include a vertical part 109V of a semiconductor pattern (109), which vertical part 109V of the semiconductor pattern (109) is interposed between the stop pattern 115 and the peripheral dielectric layer 112.

The lower dielectric layer 400 may be provided therein with a bit-line contact plug BLCP, connection circuit lines 430, and connection contact plugs 410. The bit-line contact plug BLCP, the connection circuit lines 430, and the connection contact plugs 410 may be (substantially) the same as those discussed with reference to FIG. 15.

A capacitor contact plug CCP may be disposed to extend in (e.g., penetrate) the dummy structure DST, (a portion of) the lower dielectric layer 400, and a portion of the first upper dielectric layer 300. The capacitor contact plug CCP may be (substantially) the same as that discussed with reference to FIG. 15.

A connection pad CPD may be disposed on the first upper dielectric layer 300. A through contact plug TCP may be disposed to extend in (e.g., penetrate) the first upper dielectric layer 300, the dummy structure DST, and a portion of the lower dielectric layer 400. The through contact plug TCP may be (substantially) the same as that discussed with reference to FIG. 15.

First bonding pads 450 may be disposed to electrically connect with the bit-line contact plug BLCP, the capacitor contact plug CCP, and the through contact plug TCP. The first bonding pads 450 may be (substantially) the same as that discussed with reference to FIG. 15.

A peripheral circuit structure PS may be disposed on the lower surface (e.g., the bottom surface) CSb of the lower dielectric layer 400. The peripheral circuit structure PS may be (substantially) the same as that discussed with reference to FIG. 15.

The lower surfaces (e.g., the bottom surfaces) of the first bonding pads 450 may correspondingly be in (direct) contact with the upper surfaces (e.g., the top surfaces) of the second bonding pads 35. The first bonding pad 450 and the second bonding pad 35 may constitute a single unitary shape without any interface therebetween.

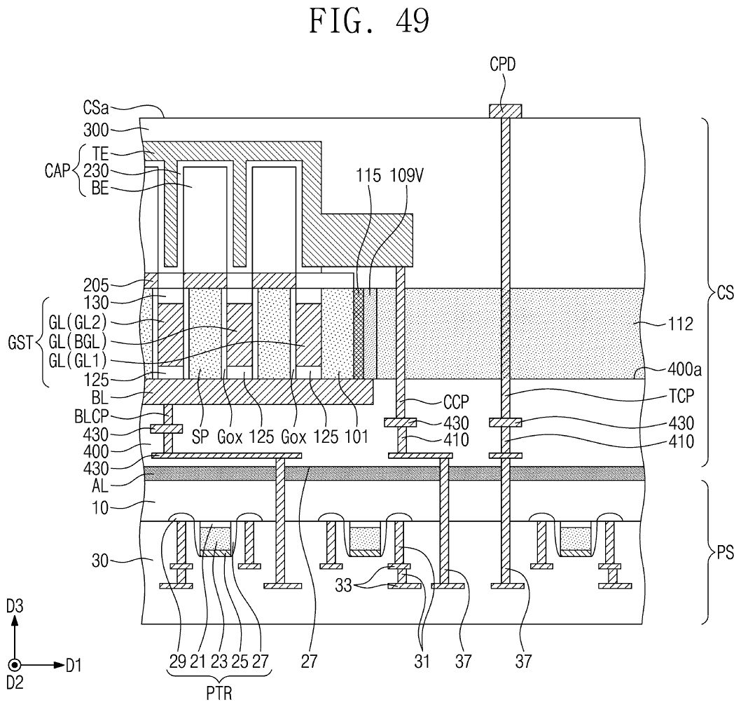

Referring to FIG. 49, according to some embodiments, the dummy structure DST may further include a vertical part 109V of a semiconductor pattern (109), which vertical part 109V of the semiconductor pattern (109) is interposed between the stop pattern 115 and the peripheral dielectric layer 112. An interface layer AL may be disposed on the lower surface (e.g., the bottom surface) CSb of the lower dielectric layer 400. A peripheral circuit structure PS may be disposed on a lower surface (e.g., a bottom surface) of the interface layer AL. The interface layer AL may be (substantially) the same as that discussed with reference to FIG. 17. As discussed with reference to FIG. 17, this case may reduce process failure and process burden compared with a case where a dielectric layer is formed to cover entire sidewalls of the peripheral through contacts 37

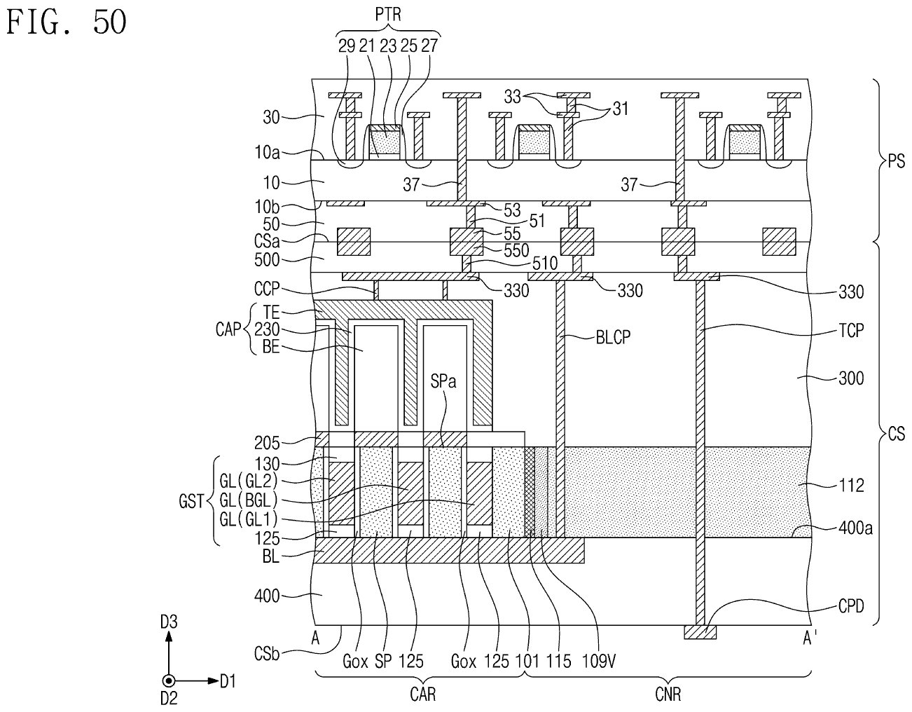

Referring to FIG. 50, according to some embodiments, the dummy structure DST may further include a vertical part 109V of a semiconductor pattern (109), which vertical part 109V of the semiconductor pattern (109) is interposed between the stop pattern 115 and the peripheral dielectric layer 112. A second upper dielectric layer 500 may be disposed on (an upper surface of) the first upper dielectric layer 300. A peripheral circuit structure PS may be disposed on an upper surface (e.g., a top surface) CSa of the second upper dielectric layer 500. The first upper dielectric layer 300, the second upper dielectric layer 500, and components included in the peripheral circuit structure PS may be (substantially) the same as those discussed with reference to FIG. 19.

The lower surfaces (e.g., the bottom surfaces) of the lower bonding pads 55 may correspondingly be in (direct) contact with the upper surfaces (e.g., the top surfaces) of the upper bonding pads 550. The lower bonding pad 55 and the upper bonding pad 550 may constitute a single unitary shape without any interface therebetween.

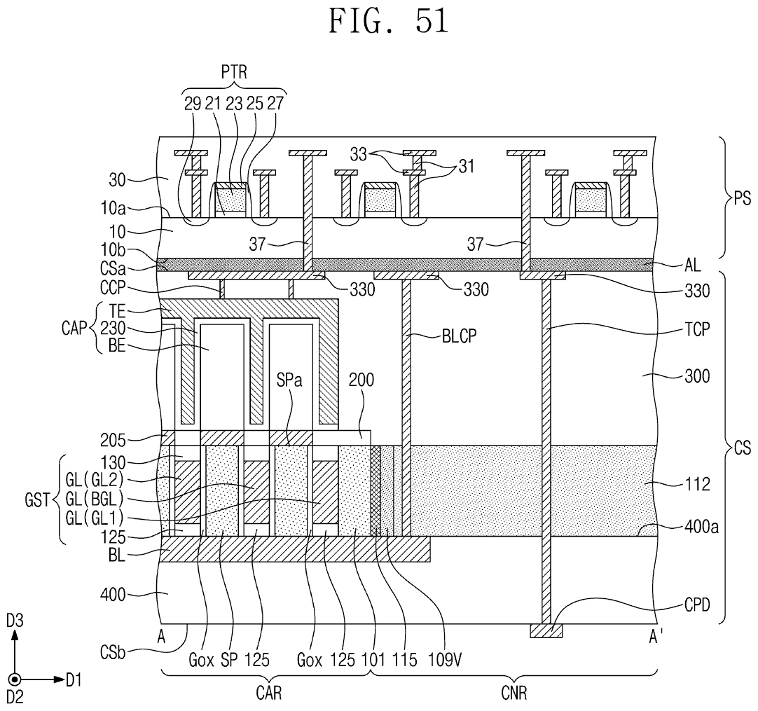

Referring to FIG. 51, according to some embodiments, the dummy structure DST may further include a vertical part 109V of a semiconductor pattern (109), which vertical part 109V of the semiconductor pattern is interposed between the stop pattern 115 and the peripheral dielectric layer 112. An interface layer AL may be disposed on (an upper surface of) the first upper dielectric layer 300. A peripheral circuit structure PS may be disposed on (an upper surface of) the interface layer AL. The interface layer AL may be (substantially) the same as that discussed with reference to FIG. 17. As discussed with reference to FIG. 17, this case may reduce process failure and process burden compared with a case where a dielectric layer is formed to cover entire sidewalls of the peripheral through contacts 37

In a semiconductor device according to the present inventive concepts, a bare silicon wafer may be used to form a cell structure, and thus there may be an advantageous effect of reducing cost.

In addition, as a cell array region and a connection region are formed to have similar (or the equal) pattern densities when a cell structure is formed, a dishing phenomenon may be reduced (e.g., prevented) during a planarization process, and a semiconductor device may improve in reliability and electrical characteristics.

Although the present invention has been described in connection with some embodiments of the present inventive concepts illustrated in the accompanying drawings, it will be understood to those skilled in the art that various changes and modifications may be made without departing from the scope of the present inventive concepts.

What is claimed is:

1. A semiconductor device, comprising:
a lower dielectric layer that includes a cell array region and a connection region that is adjacent the cell array region;
a plurality of vertical channel patterns that are spaced apart from each other in a first direction and a second direction on the cell array region of the lower dielectric layer, wherein the first direction and the second direction are parallel with an upper surface of the lower dielectric layer and intersect with each other;
a plurality of gate lines that are spaced apart from each other in the first direction and extend in the second direction on the cell array region of the lower dielectric layer, wherein at least one of the vertical channel patterns is between the gate lines in the first direction;
a capacitor structure on the cell array region of the lower dielectric layer, wherein the capacitor structure is electrically connected to the vertical channel patterns; and
a dummy structure on the connection region of the lower dielectric layer,
wherein the dummy structure includes:
a plurality of dummy substrate patterns that are spaced apart from each other in the first direction and the second direction; and
a peripheral dielectric layer between the dummy substrate patterns.

2. The semiconductor device of claim 1, wherein a first distance at which the vertical channel patterns are spaced apart from each other in the first direction is equal to a second distance at which the dummy substrate patterns are spaced apart from each other in the first direction, and
wherein a third distance at which the vertical channel patterns are spaced apart from each other in the second direction is equal to a fourth distance at which the dummy substrate patterns are spaced apart from each other in the second direction.

3. The semiconductor device of claim 1, wherein a first width in the first direction of each of the vertical channel patterns is equal to a second width in the first direction of each of the dummy substrate patterns, and
wherein a third width in the second direction of each of the vertical channel patterns is equal to a fourth width in the second direction of each of the dummy substrate patterns.

4. The semiconductor device of claim 1, further comprising:
a plurality of bit lines on the cell array region of the lower dielectric layer; and
a gate dielectric layer between one of the gate lines and a corresponding one of the vertical channel patterns,
wherein a lower surface of each of the vertical channel patterns is in contact with an upper surface of a corresponding one of the bit lines.

5. The semiconductor device of claim 1, further comprising:
an interlayer dielectric layer between the gate lines and the capacitor structure;
a first upper dielectric layer on the capacitor structure and the dummy structure on the connection region;
a capacitor contact plug that extends in the dummy structure, wherein the capacitor contact plug is electrically connected to the capacitor structure;
a plurality of bit lines in the lower dielectric layer, wherein the bit lines are electrically connected to the vertical channel patterns; and
a plurality of bit-line contact plugs in the lower dielectric layer, wherein each of the bit-line contact plugs is electrically connected to a corresponding one of the bit lines.

6. The semiconductor device of claim 5, further comprising:
a connection pad on an upper surface of the first upper dielectric layer on the connection region;
a through contact plug that extends in the first upper dielectric layer and the dummy structure on the connection region, wherein the through contact plug extends in a portion of the lower dielectric layer and is electrically connected to the connection pad;
a plurality of first bonding pads adjacent to a lower surface of the lower dielectric layer, wherein the first bonding pads are electrically connected to the bit-line contact plugs, the capacitor contact plug, and the through contact plug; and
a peripheral circuit structure on the lower surface of the lower dielectric layer,
wherein the peripheral circuit structure includes:
a plurality of peripheral circuit transistors; and
a plurality of second bonding pads electrically connected to the peripheral circuit transistors,
wherein the first bonding pads are in contact with the second bonding pads, respectively.

7. The semiconductor device of claim 6, further comprising:
a through plug line layer that extends around a side surface of the through contact plug; and
a capacitor plug line layer that extends around a side surface of the capacitor contact plug.

8. The semiconductor device of claim 5, further comprising:
a connection pad on an upper surface of the first upper dielectric layer on the connection region;
a through contact plug that extends in the first upper dielectric layer and the dummy structure on the connection region, wherein the through contact plug extends in a portion of the lower dielectric layer and is electrically connected to the connection pad;
a plurality of connection contact plugs in the lower dielectric layer;
a plurality of connection circuit lines in the lower dielectric layer, wherein the connection contact plugs and the connection circuit lines are electrically connected to the bit-line contact plugs, the capacitor contact plug, and the through contact plug;
an interface layer on a lower surface of the lower dielectric layer; and
a peripheral circuit structure on a lower surface of the interface layer,
wherein the peripheral circuit structure includes:
a plurality of peripheral circuit transistors; and
a plurality of peripheral through contacts, wherein the peripheral through contacts are electrically connected to corresponding the peripheral circuit transistors,
wherein the peripheral through contacts extend in the interface layer and are electrically connected to the connection circuit lines, respectively.

9. The semiconductor device of claim 8, further comprising:
a through plug line layer that extends around a side surface of the through contact plug; and
a capacitor plug line layer that extends around a side surface of the capacitor contact plug.

10. The semiconductor device of claim 1, wherein
each of the vertical channel patterns extends in a third direction perpendicular to the upper surface of the lower dielectric layer, and
a first thickness in the third direction of each of the vertical channel patterns is equal to a second thickness in the third direction of the peripheral dielectric layer and equal to a third thickness in the third direction of each of the dummy substrate patterns.

11. A semiconductor device, comprising:
a lower dielectric layer that includes a cell array region and a connection region that is adjacent the cell array region;
a plurality of vertical channel patterns that are spaced apart from each other in a first direction and a second direction on the cell array region of the lower dielectric layer, wherein the first direction and the second direction are parallel with an upper surface of the lower dielectric layer and intersect with each other;
a plurality of gate lines that are spaced apart from each other in the first direction and extend in the second direction on the cell array region of the lower dielectric layer, wherein at least one of the vertical channel patterns is between the gate lines in the first direction;
a capacitor structure on the cell array region of the lower dielectric layer, wherein the capacitor structure is electrically connected to the vertical channel patterns; and
a dummy structure on the connection region of the lower dielectric layer,
wherein an upper surface of each of the vertical channel patterns is coplanar with an upper surface of the dummy structure.

12. The semiconductor device of claim 11, wherein the dummy structure includes:
a peripheral dielectric layer; and
a stop pattern between the peripheral dielectric layer and the gate lines.

13. The semiconductor device of claim 12, wherein
each of the vertical channel patterns extends in a third direction perpendicular to the upper surface of the lower dielectric layer, and
a first thickness in the third direction of each of the vertical channel patterns is equal to a second thickness in the third direction of the peripheral dielectric layer and equal to a third thickness in the third direction of the stop pattern.

14. The semiconductor device of claim 12, further comprising:
an interlayer dielectric layer between the gate lines and the capacitor structure;
a first upper dielectric layer on the capacitor structure and the dummy structure on the connection region;
a capacitor contact plug that extends in the dummy structure, wherein the capacitor contact plug is electrically connected to the capacitor structure;
a plurality of bit lines in the lower dielectric layer, wherein the bit lines are electrically connected to the vertical channel patterns; and
a plurality of bit-line contact plugs in the lower dielectric layer, wherein the bit-line contact plugs are electrically connected to the bit lines, respectively.

15. The semiconductor device of claim 14, further comprising:
a connection pad on an upper surface of the first upper dielectric layer on the connection region;
a through contact plug that extends in the first upper dielectric layer and the dummy structure on the connection region, wherein the through contact plug extends in a portion of the lower dielectric layer and is electrically connected to the connection pad;
a plurality of first bonding pads adjacent to a lower surface of the lower dielectric layer, wherein the first bonding pads are electrically connected to the bit-line contact plugs, the capacitor contact plug, and the through contact plug, respectively; and
a peripheral circuit structure on the lower surface of the lower dielectric layer,
wherein the peripheral circuit structure includes:
a plurality of peripheral circuit transistors; and
a plurality of second bonding pads electrically connected to the peripheral circuit transistors,
wherein the first bonding pads are in contact with the second bonding pads, respectively.

16. The semiconductor device of claim 14, further comprising:
a connection pad on an upper surface of the first upper dielectric layer on the connection region;
a through contact plug that extends in the first upper dielectric layer and the dummy structure on the connection region, wherein the through contact plug extends in a portion of the lower dielectric layer and is electrically connected to the connection pad;
a plurality of connection contact plugs in the lower dielectric layer;
a plurality of connection circuit lines in the lower dielectric layer, wherein the connection contact plugs and the connection circuit lines are electrically connected to the bit-line contact plugs, the capacitor contact plug, and the through contact plug;
an interface layer on a lower surface of the lower dielectric layer; and
a peripheral circuit structure on a lower surface of the interface layer,
wherein the peripheral circuit structure includes:
a plurality of peripheral circuit transistors; and
a plurality of peripheral through contacts, wherein the peripheral through contacts are electrically connected to the peripheral circuit transistors,
wherein the peripheral through contacts extend in the interface layer and are electrically connected to the connection circuit lines, respectively.

17. The semiconductor device of claim 12, further comprising:
a vertical part of a semiconductor pattern, wherein the vertical part of the semiconductor pattern is between the stop pattern and the peripheral dielectric layer.

18. The semiconductor device of claim 17, wherein
each of the vertical channel patterns extends in a third direction perpendicular to the upper surface of the lower dielectric layer, and
a first thickness in the third direction of each of the vertical channel patterns is equal to a second thickness in the third direction of the peripheral dielectric layer, equal to a third thickness in the third direction of the stop pattern, and equal to a fourth thickness in the third direction of the vertical part of the semiconductor pattern.

19. A semiconductor device, comprising:
a lower dielectric layer that includes a cell array region and a connection region that extends from the cell array region;
a bit line on the cell array region of the lower dielectric layer, wherein the bit line extends in a first direction;
a plurality of vertical channel patterns that are spaced apart from each other in the first direction on the bit line;
a plurality of gate lines on the bit lines, wherein ones of the gate lines are adjacent to corresponding ones of the vertical channel patterns, the gate lines intersect the bit line and extend in a second direction that intersects the first direction;
a capacitor structure on the vertical channel patterns, wherein the capacitor structure includes a plurality of lower electrodes that are spaced apart from each other in the first direction, a dielectric layer on the lower electrodes, and an upper electrode on the dielectric layer and the lower electrodes; and
a dummy structure on the connection region of the lower dielectric layer,
wherein the dummy structure includes:
a plurality of dummy substrate patterns that are spaced apart from each other in the first direction; and
a dummy dielectric pattern between the dummy substrate patterns.

20. The semiconductor device of claim 19, wherein a first distance at which the vertical channel patterns are spaced apart from each other in the first direction is equal to a second distance at which the dummy substrate patterns are spaced apart from each other in the first direction.
